(19) United States
(12) Patent Application Publication
(10) Pub. No.: US 2024/0220742 A1
(43) Pub. Date: Jul. 4, 2024

(54) MULTIPLY-ACCUMULATE SUCCESSIVE APPROXIMATION DEVICES AND METHODS

(71) Applicant: ROBERT BOSCH GMBH, Stuttgart (DE)

(72) Inventors: Kenneth Edward WOJCIECHOWSKI, Cupertino, CA (US); Sangwoo LEE, Cupertino, CA (US)

(21) Appl. No.: 18/148,266

(22) Filed: Dec. 29, 2022

(51) Int. Cl. G06J 1/00; H03M 1/46

(52) U.S. Cl. CPC G06J 1/00; H03M 1/462; H03M 1/466; G11C 11/413

(57) ABSTRACT

A multiply-accumulate successive approximation (MASAR) column is provided. The MASAR column includes a plurality of MASAR cells, each including a multiplier configured to perform digital multiplication between an input activation received to an input and an operand to compute a result, and a unit capacitor configured to store the result as analog charge. The MASAR column further includes digital logic configured to perform analog summation of the analog charge of the unit capacitors of the plurality of MASAR cells to determine a digital output of the multiplication.

### TECHNICAL FIELD

Aspects of the present disclosure generally relate to hardware and methods for improved implementation of multiplication and multiply-accumulate functions.

### BACKGROUND

Current machine learning (ML), and especially neural network (NN) models, may include a combination of multiple layers with varying number of weights in each layer. Each layer may compute a number of multiply-accumulate (MAC) operations involving the stored weights as well as the input to each layer. While NNs have been very successful in classification tasks (inference), as the difficulty of tasks increase, larger networks with more layers and more weights per layer are needed. As the NN size increases the required memory for weights and the computational power needed to implement the network increases as well. In typical digital hardware implementations, the large number of weights cannot all be stored on the same application-specific integrated circuit (ASIC) that performs the MAC operations and significant data transfer with off-chip memory is required. Both the MAC operation, which consists of a number of multiplication and accumulate steps, and the data transfer can be costly in terms of time and energy.

### SUMMARY

In one or more illustrative examples, a multiply-accumulate successive approximation (MASAR) column is provided. The MASAR column includes a plurality of MASAR cells, each including a multiplier configured to perform digital multiplication between an input activation received to an input and an operand to compute a result, and a unit capacitor configured to store the result as analog charge. The MASAR column further digital logic configured to perform analog summation of the analog charge of the unit capacitors of the plurality of MASAR cells to determine a digital output of the multiplication by configuring the unit capacitors as a capacitive digital to analog converter (CDAC) in a successive approximation register (SAR) analog to digital converter (ADC).

In one or more illustrative examples, a MASAR column includes a plurality of MASAR cells, each including a multiplier configured to perform digital multiplication between an input activation received to an input and an operand to compute a result, a unit capacitor configured to store the result as analog charge, and a multiplexer (MUX) having at least first and second inputs and an output, wherein the MUX is configured to receive the result on the first input, to receive a bit-guess input from the digital logic on the second input, and to apply the output to the unit capacitor. The MASAR column further includes digital logic configured to utilize a successive approximation register (SAR) algorithm to perform analog summation of the analog charge of the unit capacitors of the plurality of MASAR cells to determine a digital output of the MAC, by controlling the individual MASAR cell unit capacitances via the bit-guess input to form a capacitive digital to analog converter (CDAC). The MASAR column further includes a comparator having a comparator input and a comparator output, wherein each of the unit capacitors is connected to the comparator input via a common bit line, and the digital logic is configured to receive the comparator output, wherein the common bit line is connected to a RESET switch controllable by a RESET line. The MUX is further configured to be controlled by an enable MAC control line to select between (i) storing the result to the unit capacitor and (ii) utilizing the unit capacitor to determine the analog summation of the charge. The RESET switch is further configured to be controlled to select between (i) connecting the common bit line to a reference voltage, and (ii) disconnecting the common bit line from the reference voltage.

In one or more illustrative examples, a method of performing multiplication and multiply-accumulate functions using a plurality of MASAR cells and digital logic includes performing digital multiplication, utilizing multipliers of each of the plurality of MASAR cells, between an input activation received to an input of the respective MASAR cell and an operand to compute a result; storing the result of the digital multiplication as analog charge in unit capacitors of the respective MASAR cells; and performing analog summation of the analog charge of the unit capacitors of the plurality of MASAR cells, under control of digital logic, to determine a digital output of the multiplication by configuring the unit capacitors as a capacitive digital to analog converter (CDAC) in a successive approximation register (SAR) analog to digital converter (ADC).

In one or more illustrative examples, a MASAR array for performing a plurality of parallel MAC calculations is provided. The MASAR array includes a plurality of MASAR columns, each MASAR column including a plurality of MASAR cells, each of the MASAR cells including a multiplier configured to perform digital multiplication between an input activation received to an input and an operand to compute a result, and a unit capacitor configured to store the result as analog charge. The MASAR array further includes global digital logic configured to control analog summation of the analog charge of the unit capacitors of the plurality of MASAR cells to determine a digital output of the multiplication.

In one or more illustrative examples, a parallel multi-bit MASAR architecture for performing multi-bit multiplication is provided. The parallel architecture includes a two-dimensional array of MASAR cells, configured to collectively multiply each digit of a multi-bit input activation by each digit of a multi-bit operand, the MASAR cells being arranged into MASAR columns by bit significance, such that summation is performed in analog via charge summation for each column to determine a multi-bit digital output of the multiplication for each MASAR column. The parallel architecture further includes a plurality of scalars, each configured to digitally scale the multi-bit digital outputs of each MASAR column by the bit significance to produce scaled digital outputs. The parallel architecture further includes an adder configured to add the scaled digital outputs to produce a multi-bit digital result of the multiplication.

In one or more illustrative examples, a serial multi-bit MASAR architecture for performing multi-bit multiplication is provided. The serial architecture includes a single row of MASAR cells, configured to multiply a single bit of a multi-bit input activation by each digit of a multi-bit operand, the MASAR cells being arranged into MASAR columns by bit significance, such that summation is performed in analog via charge summation for each column to determine intermediate results of the multiplication for each single bit of the multi-bit input activation. The serial architecture further includes a plurality of scalars, each configured to digitally scale the intermediate results of each MASAR column by the bit significance to produce scaled digital outputs. The serial architecture further includes registers and an adder configured to add the scaled digital outputs to the registers. The serial architecture further includes control logic configured to iterate the single row of MASAR cells through each bit of the multi-bit input activation and to utilize the adder to sum a multi-bit digital result of the multiplication using the registers.

### BRIEF DESCRIPTION OF THE DRAWINGS

FIG. 1 illustrates an example multiply-accumulate successive approximation (MASAR) column, in accordance with an embodiment of the disclosure;

FIG. 2A illustrates a functional diagram of a MASAR cell that supports single bit precision MAC computation, with embedded static random access memory (SRAM);

FIG. 2B illustrates a functional diagram of a MASAR cell that supports single bit precision MAC computation, without embedded SRAM;

FIG. 2C illustrates a functional diagram of a MASAR cell that supports single bit precision MAC computation, in simplified form;

FIG. 3A illustrates a functional diagram of a single ended (one bit line) Multibit MASAR cell;

FIG. 3B illustrates a functional diagram of a differential multibit MASAR cell;

FIG. 3C illustrates a simplified functional diagram of a MASAR cell during MAC mode;

FIG. 3D illustrates a simplified functional diagram of a multibit MASAR cell which can be used for MAC or SAR modes;

FIG. 4A illustrates a first portion of the operation of the MASAR column in the MAC mode;

FIG. 4B illustrates a second portion of the operation of the MASAR column in the MAC mode;

FIG. 4C illustrates a second portion of the operation of the MASAR column in the MAC mode;

FIG. 5A illustrates a first portion of the operation of the MASAR column in the SAR mode;

FIG. 5B illustrates a second portion of the operation of the MASAR column in the SAR mode;

FIG. 6A illustrates a diagram of a SAR ADC with a CDAC;

FIG. 6B illustrates diagram of a SAR ADC N-bit CDAC showing binary scaling of the capacitors and connection of the ADC guess bits, BG[0:N−1];

FIG. 6C illustrates diagram of a MASAR column with Nᵣ rows of MASAR cells;

FIG. 7 illustrates an example MASAR column with 32 rows;

FIG. 8A illustrates an example of ADC guess bit connections for quantization to 4 bits of a 5-bit MAC result for a MASAR column with 32 rows;

FIG. 8B shows an example of the ADC guess bit connections for quantization to 3 bits of a 5-bit MAC result for a MASAR column with 32 rows;

FIG. 9 illustrates an example of spatial distribution of ADC guess bits for a MASAR column with 32 rows;

FIG. 10 illustrates an example MASAR column of arbitrary size N;

FIG. 11 illustrates an example MASAR column of size N=6;

FIG. 12 illustrates an example of the MASAR column in combination with a graph of the ADC output values;

FIG. 13 illustrates an example coarse-precision mapping of the output values of the MASAR column;

FIG. 14 illustrates a first example fine-precision mapping of a subset of the output values of the MASAR column;

FIG. 15 illustrates a second example fine-precision mapping of a subset of the output values of the MASAR column;

FIG. 16 illustrates a third example fine-precision mapping of a subset of the output values of the MASAR column;

FIG. 17 illustrates a fourth example fine-precision mapping of a subset of the output values of the MASAR column;

FIG. 18 illustrates a fifth example fine-precision mapping of a subset of the output values of the MASAR column;

FIG. 19 illustrates a sixth example fine-precision mapping of a subset of the output values of the MASAR column;

FIG. 20 illustrates an example mid-precision shifted mapping of a subset of the output values of the MASAR column;

FIG. 21 illustrates an alternate example mid-precision shifted mapping of a subset of the output values of the MASAR column;

FIG. 22 illustrates an example MASAR array of a group of MASAR columns;

FIG. 23 illustrates an example MASAR array in a serial configuration with digital logic;

FIG. 24A illustrates a first SAR ADS conversion of the first bit from the first MASAR column of the MASAR array;

FIG. 24B illustrates a second SAR ADS conversion of the second bit from the second MASAR column of the MASAR array;

FIG. 24C shows the conversion of the N^{th} bit from the N^{th} MASAR column of the MASAR array;

FIG. 25 illustrates an example MASAR array in a parallel configuration with digital logic;

FIG. 26 illustrates an example MASAR array in a parallel configuration showing the routing of ADC guess signals;

FIG. 27 illustrates an example of 4-bit signed integer multiplication in a parallel case;

FIG. 28A illustrates a parallel 4-bit signed integer multiplier;

FIG. 28B illustrates a MASAR array implementing the parallel 4-bit signed integer multiplier of FIG. 28A;

FIG. 29A illustrates a parallel 4-bit signed integer multiplier;

FIG. 29B illustrates a product representation of the diagram of FIG. 29A;

FIG. 30 illustrates an example of a single channel/kernel multibit MASAR array for calculating N_{M} 4-bit signed integer MACs;

FIG. 31 illustrates an example of multiple channels/kernels in parallel to accommodate larger parallel computations;

FIG. 32 illustrates an example of a single channel 8-bit signed integer parallel MASAR array accelerator;

FIG. 33A illustrates an example of a MASAR array implementing a serial arrangement for 4-bit signed integers;

FIG. 33B shows a diagram of a serial MASAR product cell for Nₚ=4-bits with comparators and digital logic;

FIG. 34 illustrates example operations performed for the 4-bit signed integer case using the MASAR array of FIG. 33A;

FIG. 35 illustrates an example serial 4-bit precision MASAR array for computing a MAC with N_{M} products in K=N_{K} channels or kernels;

FIG. 36 illustrates an example two's complement bit serial architecture, using 3-bit activations and weights;

FIG. 37 illustrates an example of addition of the partial products of the serial computation performed by the architecture of FIG. 36;

FIG. 38 illustrates an example of the first step of the computation of the partial products of FIG. 37;

FIG. 39 illustrates an example of the second step of the computation of the partial products of FIG. 37; and

FIG. 40 illustrates an example of the third step of the computation of the partial products of FIG. 37.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications.

The computational workload of convolutional neural networks (CNNs) may be dominated by multiply and accumulate or MAC operations (also known as dot products). These operations are essentially sums of products between input activations, Aᵢ and weights, Wᵢⱼ, of the CNNs. Hence there is interest in hardware (HW) based building blocks that can accelerate MAC operations while improving performance such as energy/MAC, Area/MAC and Clock cycles/MAC.

Aspects of the disclosure relate to a new building block for implementing MAC functions in HW using both digital and analog circuit techniques. These approaches may enable possible architectures going from a single multiplier to large scale MAC arrays that enable parallel multiply and accumulation of data and weights for artificial intelligence (AI)/ML applications. Such architectures may be adapted from 1 bit to multi bit (4 bit, 8 bit) computational precision of the weights and activations.

An array may be made up of modular processing elements or cells. These processing elements may be configured such that a column of cells can perform a digital input to digital output MAC computation without the need of an additional analog to digital converter (ADC). A column of such cells may perform a mixed signal MAC calculation which results in an analog charge proportional to the MAC computation result. The analog result is then converted to digital using the same column of cells configured as a SAR ADC. These cells may be referred to as MAC+SAR, or MASAR cells. The MASAR cells are the processing elements that enable all functions for MAC calculation and analog to digital conversion. Thus, the proposed approach uses the same processing element array for digital multiplication and charge summation as well as for the ADC conversion.

The MASAR modular processing elements may be used to implement multibit precision multiplications and MAC computations, which is useful for ML/AI HW acceleration. Each MASAR cell uses a unit capacitance to store the results of the 1-bit multiplications in charge. A column of MASAR cells can be used sum the 1-bit products in charge using charge redistribution. The column of MASAR cells also provide the ability to convert the charge to a digital value by configuring the column of MASAR cells into a SAR ADC. The SAR is used to convert the sum of products back to a digital representation. These new building blocks (MASAR cells) enable both MAC and SAR functions when used in columns (MASAR columns). MASAR columns can be placed in parallel to form MASAR arrays which can perform multibit precision MAC computations.

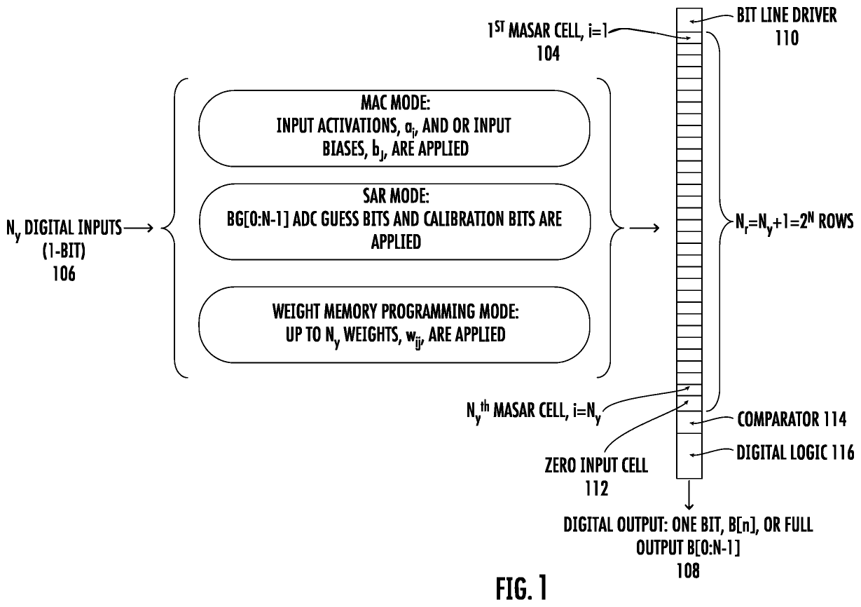

FIG. 1 illustrates an example MASAR column 102, in accordance with an embodiment of the disclosure. The MASAR columns 102 includes a plurality of MASAR cells 104. The MASAR column 102 may include digital inputs 106 configured to receive various inputs. The input vectors may be of size N_{y}. As described herein, i may refer to the MASAR cell 104 row index, where i=1 . . . N_{y}, and j may refer to the column index. In the illustrated example, the column includes Nᵣ=2^{N} rows of MASAR cells 104.

In a weights programming mode, weights wᵢⱼ may be applied to the digital inputs 106 of the MASAR cells 104. These weights may be stored in the MASAR cells 104 and used in a two-mode runtime approach to perform digital-in to digital-out MAC computations. Weights may be stored in each MASAR cell or only in some or not at all. In some examples, the weights may be stored outside of the MASAR columns. The weight programming mode may be specific to when the weights are stored in the MASAR columns or cells. In this case it may be advantageous to use the same inputs (e.g., wires) to the cells for programming weights and applying input activations. It should be noted that more than one weight may be stored in each MASAR cell in some examples (e.g., each MASAR cell may contain multiple memory cells), which may be advantageous for computation of ML algorithms.

This two-mode approach includes a MAC mode (multiply+charge summation) followed by a SAR mode (charge to digital). It should be noted that memory can be in every MASAR cell 104 or only certain rows in the MASAR column 102 may have memory. For cases where not all MASAR cells 104 have memory, there are different options for how memory can be distributed in a MASAR column 102. Some examples are discussed herein. Also programming of the memory can be do done in multiple ways. One way would be programming the weights wᵢⱼ one column j at a time. In this case a vector of weight wᵢⱼ may be applied to the inputs of the MASAR column 102. Other options may include to program one row i at a time, program individual MASAR cell 104 memories one at a time or multiple MASAR cell 104 memories all at once through an entire MASAR array.

In the MAC mode, input activations aᵢ, or input biases bᵢ, may be applied to each of the cells. These values may be applied to the digital inputs 106. In a first aspect (MAC step 1), multiple 1-bit digital multiplications are performed digitally. In a second aspect (MAC step 2), the multiplication results are stored in charge. In a third aspect (MAC step3), the results of the multiplications are summed using charge sharing/redistribution on the MASAR column 102. The total charge stored on the MASAR column 102 as unit capacitances represents the analog value of the result of the MAC computation.

In the SAR mode, conversion of the charge back to digital is accomplished by configuring the unit capacitors of the MASAR cells 104 in the column as a capacitive digital to analog converter (CDAC) 115. The column is used with a single comparator to perform a successive approximation analog to digital conversion of the stored charge in the column. In the SAR mode, ADC guess bits BGᵢ[0:N−1] may be utilized to facilitate the conversion back to digital.

The MASAR column 102 may produce digital outputs 108 representative of multiplication of the input i with the stored weights wᵢⱼ. These digital outputs 108 may provide a single bit B[N] result, or, in other examples, may include a full output B[0:N−1]. The MASAR columns 102 may further include a bit line driver 110, a zero input cell 112, a comparator 114, and digital logic 116. These components are discussed in further detail below.

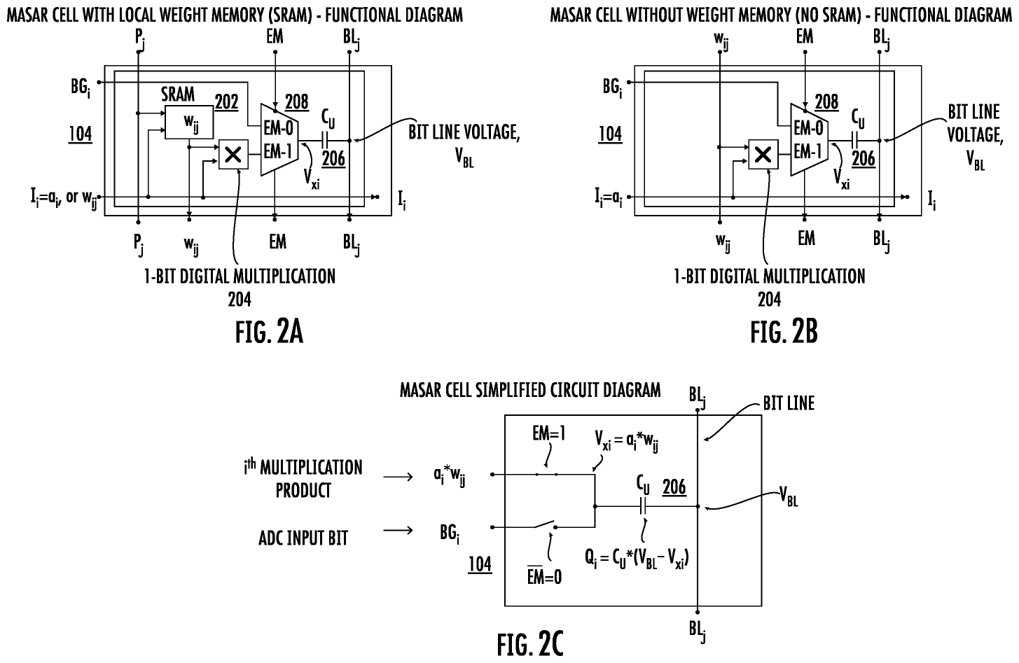

FIG. 2A illustrates a functional diagram of a MASAR cell 104 that supports single bit precision MAC computation, with embedded SRAM 202. As shown, the MASAR cell 104 includes SRAM 202 which may be used to store the programming weight wᵢⱼ for the cell. It should be noted that while many examples herein mention SRAM, the memory in the MASAR cells 104 may be other types of memory besides SRAM. The MASAR cell 104 may also include a 1-bit digital multiplier 204 (e.g., an AND gate) configured to multiply the weight wᵢⱼ by the input received to the digital input 106 (here Iᵢ). Pⱼ may be used to select between applying Iᵢ to the SRAM 202 or to the multiplier 204. The MASAR cell 104 may also include a capacitor 206, of unit capacitance, configured to store the value computed by the multiplier 204. The MASAR cell 104 may further include digital logic 116 in the form of a multiplexer (MUX) 208, where the MUX 208 is configured to select between applying the output of the multiplier 204 to the capacitor 206 or resetting the capacitor 206 to a defined value.

The MASAR cell 104 can be configured to calculate a 1-bit multiplication between an input, (Iᵢ=aᵢ in MAC mode) and store it as a charge on the unit capacitor 206 as unit capacitance Cᵤ. The output of the MASAR cell 104 may be provided to the BLⱼ, as the j^{th} bit line, for charge summation. By setting the EM signal, the unit capacitance may be stored to the capacitor 206, and by resetting the EM signal the capacitor 206 may be reset. Additionally, the EM signal may be used to select between MAC mode in which the capacitance is determined by the multiple, and the collective capacitive across MASAR cells 104 is measured in the SAR mode.

FIG. 2B illustrates a functional diagram of a MASAR cell 104 that supports single bit precision MAC computation, without embedded SRAM 202. As compared to the MASAR cell 104 shown in FIG. 2A, in the MASAR cell 104 of FIG. 2B the weight wᵢⱼ is applied to the MASAR cell 104 for each use, as opposed to being retrieved from the local weight memory SRAM 202.

FIG. 2C illustrates a functional diagram of a MASAR cell 104 that supports single bit precision MAC computation, in simplified form. This simplified diagram is used throughout the disclosure to explain further aspects of the operations of the MASAR cell 104 and MASAR column 102.

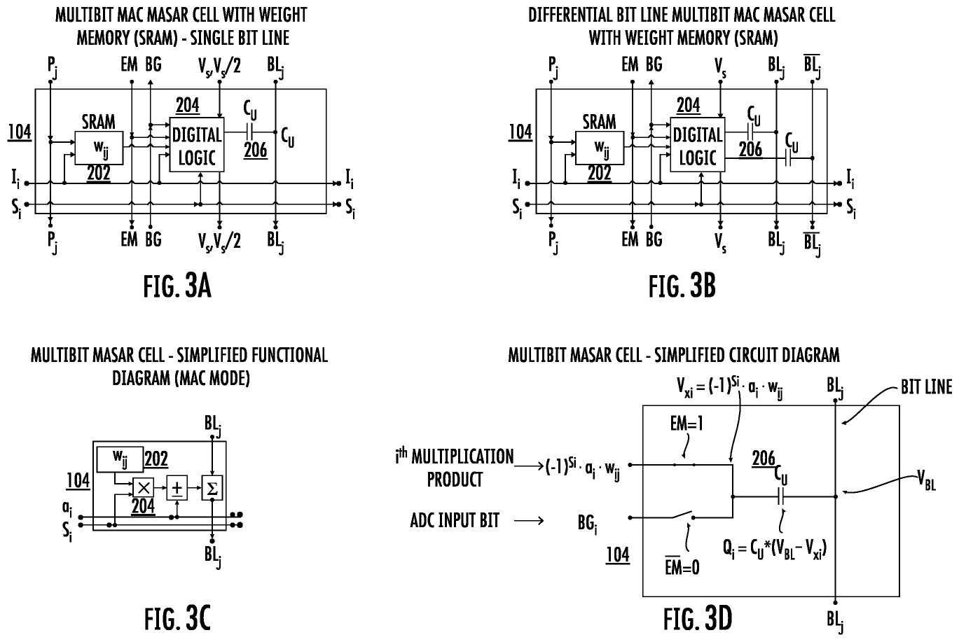

It should be noted that single bit computation does not require sign bits, as 1-bit or single bit multiplication does not include a sign. For signed integer multiplication a sign bit may be utilized. Note that a sign bit is not required in cases that do not use signed integer computation, such as binary coded decimal. FIGS. 3A-3D collectively illustrate example MASAR cells 104 for multibit signed integer MACs, where (Nₚ≥2).

FIG. 3A illustrates a functional diagram of a single ended (one bit line) multibit MASAR cell 104. As compared to the MASAR cells 104 shown in FIGS. 2A-2C, in FIG. 3A a sign bit Sᵢ is additionally present. Additionally, the MUX 208 is replaced with digital logic 116 configured to handle the additional signaling required for the sign bit Sᵢ.

FIG. 3B illustrates a functional diagram of a differential multibit MASAR cell 104. In this example, there is an additional line for a differential output (the bitwise opposite of the existing output). FIG. 3C illustrates a simplified functional diagram of a MASAR cell 104 during MAC mode. As shown, the sign is now taken into account with respect to the summation of the capacitor 206 unit capacitive across the MASAR cells 104. FIG. 3D illustrates a simplified functional diagram of a multibit MASAR cell 104 which can be used for MAC or SAR modes.

Table 1 illustrates a description of the signaling shown in FIGS. 2A-3D.

TABLE 1
1-bit and Multibit MASAR Cell Control Signal Definitions

| Signal Name | Description |
|---|---|
| Iᵢ | Is an input to the MASAR cell 104 used to supply a value for Wᵢⱼ while |
| | programming the weight memory in the MASAR cell 104. It is also used to supply |
| | the input activation, aᵢ. Iᵢ is routed to the MASAR cells 104 on the same row (i^{th} |
| | row) of multiple MASAR columns 102 on what is referred to herein as a word line. |
| BGᵢ | Is an input to the MASAR cell 104 used to apply the “Bit Guess”. BGᵢ comes from |
| | the SAR ADC control logic and is needed to enable conversion of the stored charge |
| | on the MASAR Column 102 bit line(s) to a digital value. |
| Pⱼ | Serves as a column select for programming of the memory in each cell. Setting Pⱼ |
| | high selects the j^{th} MASAR Column 102 for programming. Typically, only one |
| | column is programmed at a time. When high the weight memory is set, W_{i, j} = Iᵢ. |
| | When low, the value applied to Iᵢ is used as input to the multiplier 204. |
| EM | “Enable MAC” Control bit. When high (or 1) it enables the storage of the |
| | multiplication product, Aᵢ · W_{i, j} as a charge, Qi, on the unit capacitor 206, Cᵤ. |
| | When low, it allows for operation in the SAR A/D conversion mode. |
| BLⱼ, B̅L̅_{J} | j^{th} bit line - charge summation occurs on the bit line. The voltage on the bit line |
| | is V_{BL}_{ⱼ}. All MASAR cells 104 in a MASAR column 102 are connected to the same |
| | bit line(s). Note RESET is a global signal use to reset the bit line voltage. If |
| | RESET = 1, V_{BL}_{ⱼ} is reset to Vs. For the differential case there is an additional bit |
| | line bar or B̅L̅_{ι}. This bit line is the opposite polarity from BLⱼ. |
| Sᵢ | Sign bit of the multiplication. It is the exclusive or (XOR) of the most significant |
| | bits, most significant bits (MSBs), of the weights and activations. This is used for |
| | multibit (unless two's-complement is being used). |

Table 2 illustrates values of the signaling with respect to the different modes and operations that are performed by the MASAR column 102 and MASAR cells 104.

TABLE 2
Modes of the MASAR Cell/Columns with signal values

| Cell Mode | Pⱼ | EM | Iᵢ | RESET | Description |
|---|---|---|---|---|---|
| MAC | 0 | 1 | a | 1 | 1-bit multiplication aᵢ · wᵢⱼ |
| (Store Charge) | | | | | Stored as charge on the unit |
| | | | | | capacitor 206 |
| MAC | 0 | 1 | aᵢ | 0 | Stored charge redistributed on |
| (Sum Charge) | | | | | all capacitors 206 in a MASAR |
| | | | | | column 102 |
| SAR ADC | 0 | 0 | X = | 0 | Unit capacitors 206 in |
| (ADC conversion) | | | don't | | MASAR column 102 used as a |
| | | | care | | SAR ADC capacitor 206 |
| | | | | | digital-to-analog converter |
| | | | | | (DAC). Controlled by ADC |
| | | | | | guess bits, BGᵢ |
| Weight Memory | 1 | 0 | New | 1 | SRAM 202 weight bits of the |
| Programming (WMP) | | | wᵢⱼ | | j^{th} MASAR column 102 are |
| | | | | | updated to new value placed |
| | | | | | row input, Iᵢ. |

Table 3 illustrates further definitions of terms with respect to the MASAR column 102.

TABLE 3
MASAR Column Definitions

| Name | Description |
|---|---|
| i, j | i = 1 . . . N_{y}, is the MASAR (Column/Array) row index. |
| | j = 1 . . . Nₓ, is MASAR array column index. |
| | Both are integers |
| Nᵣ | The number of rows in the MASAR columns 102. |
| | Nᵣ is assumed to be a power of 2. i.e. Nᵣ = 2^{k}. k is an integer. |
| Nₓ | Number of MASAR columns 102 in a MASAR array. |
| N_{y} | Number of MASAR cells 104 in the column that process inputs. MAX(N_{y}) = |
| | Nᵣ − 1 |
| N_{BG} | Number of output bits, B, in a MASAR column 102. |
| | This may also refer to the SAR ADC resolution in bits. Note the number of |
| | output bits changes depends on the arithmetic used. N_{BG} ≤ log₂(Nᵣ) for 2's |
| | complement number representation and N_{BG} ≤ log₂(Nᵣ) + 1 for signed integer |
| | number representation. |
| aᵢ | 1-bit Input activations to the MASAR column 102. |
| wᵢⱼ | 1-bit weight stored in the i^{th} row and j^{th} column MASAR cell 104. |
| | NOTE: Weight storage is not required in all MASAR cells 104. |
| V_{CO, j} | Is the one-bit output of the j^{th} MASAR column 102 comparator 114. |
| BGⱼ[0: N_{BG} − 1] | ADC guess bits for the j^{th} MASAR column 102. |
| | Used for SAR ADC conversion of MAC result. |
| Bⱼ[0: N_{BG} − 1] | Digital output of the j^{th} MASAR column 102. |
| | This value can be one bit, Bⱼ[x], where x is the current bit that has been resolved |
| | by the SAR ADC algorithm. |
| | Or, this value can be all bits of the MAC result: Bⱼ[0: NBG − 1]. This is |
| | dependent on the location of the SAR digital logic 116. |
| | NOTE: The full SAR digital logic 116 does not have to be implemented within |
| | the digital logic 116 of the MASAR column 102. |

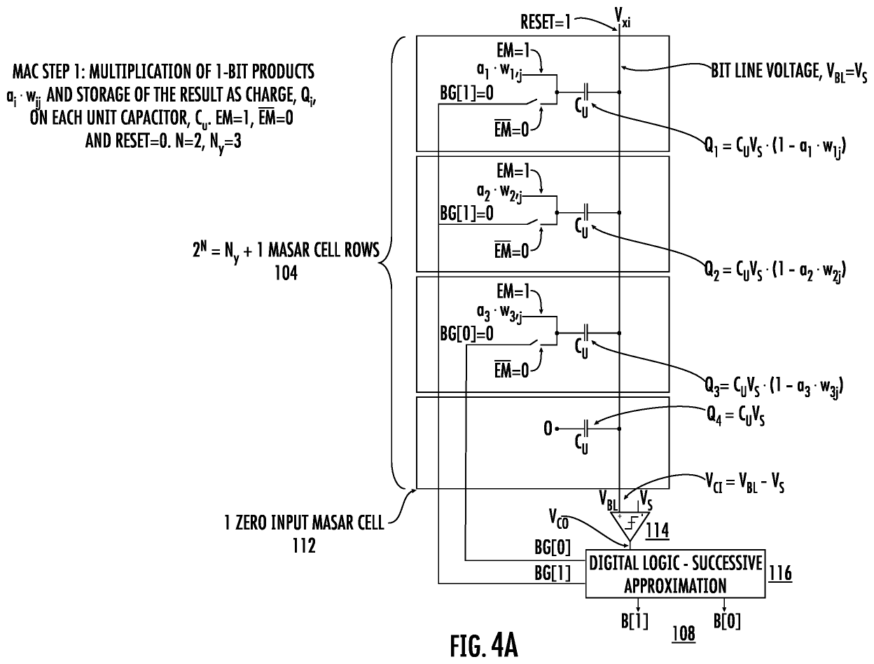

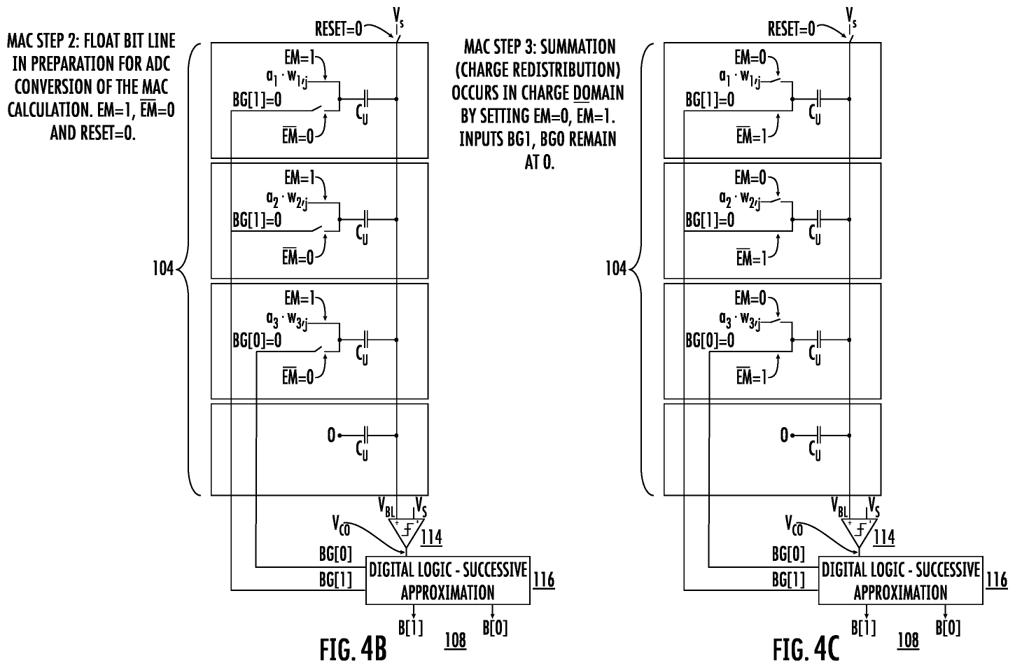

FIG. 4A illustrates a first portion (MAC step 1) of the operation of the MASAR column 102 in the MAC mode. The illustrated MASAR column 102 includes four MASAR cells 104, the comparator 114, and SAR digital logic 116. In this example N_{BG}=2, and there are Nᵣ=4 rows of MASAR cells 104. These MASAR cells 104 include N_{y}=3 active MASAR cells 104, plus one zero input cell 112. The zero input cell 112 is always set to zero, as no input is ever applied to that MASAR cell 104. Note there are cases where a zero input cell 112 is not required, e.g., where the MASAR column 102 is not using full resolution conversion.

Here, the MASAR column 102 is shown in the first portion of the MAC. In this first portion, all products, aᵢ·wᵢⱼ, are being applied to the MASAR column 102 for computation by the multiplier 204. At this point, the ADC guess bits are set to zero (BG₀=BG₁=0). Additionally, the signal EM is set such that EM=1, E̅M̅=0, thereby forcing the products on the “cell” side of the unit capacitors 206. The signal RESET is set such that RESET=1, forcing the bit line side of the unit capacitors 206 to the reference voltage, Vₛ. Further aspects of the signaling of the MASAR column 102 are illustrated in Table 4.

TABLE 4
Simplified MASAR Column Signal Definitions

| Signal Name | Description |
|---|---|
| RESET | When RESET = 1, it forces the bit line voltage |
| | to reference voltage, V_{S}. |
| V_{BL} | The voltage on the MASAR column 102 bit line |
| V_{S} | Reference voltage for the MASAR array |
| V_{CI} = | Input to the comparator 114 in the MASAR column 102 |
| V_{BL} − V_{S} | |
| V_{CO} | Output of the comparator 114 |
| Bᵢ | Digital outputs of the SAR logic. These represent the |
| | digitized output of the MAC |
| | operation performed by MASAR column 102. |

Referring more specifically to the MAC step 1 aspect, the 1-bit products, aᵢ·wᵢⱼ, are stored as a charge, Qᵢ, (Eq. 1) on the unit capacitors 206 of the MASAR cell 104. Here, EM=1, E̅M̅=0. The charge is thereby stored by applying the product, aᵢ·wᵢⱼ, to the “cell” side of each unit capacitor 206 or node Vₓᵢ in the cell. At the same time, the common side of the unit capacitors 206 or bit line is forced to the reference voltage, V_{S} by setting RESET=1. Eq. 2 is the total charge, Qₜₒₜ stored in the MASAR column 102 after MAC step 1.

$$\begin{matrix}{Q}_{i} = \{ \begin{matrix}{C}_{u} {V}_{s} \cdot ( 1 - {a}_{i} {w}_{i , j} ) , i \leq {N}_{y} \\ {C}_{u} {V}_{s} , i = {2}^{N} = {N}_{y} + 1\end{matrix} & Eq . 1 \\ {Q}_{tot} = {\sum }_{i = 1}^{{2}^{N}} {Q}_{i} = {C}_{u} {V}_{s} + {C}_{u} {V}_{s} {\sum }_{i = 1}^{{N}_{y}} ( 1 - {a}_{i} {w}_{i , j} ) & Eq . 2 \\ {C}_{TOT} = {2}^{N} {C}_{u} & Eq . 3\end{matrix}$$

Note that for this MASAR column 102 with 2^{N} cells there is a maximum of N_{y} inputs where N_{y}=2^{N}−1. One MASAR cell 104 (the zero input cell 112) has zero input and N_{y} cells have inputs. This is to ensure full analog to digital conversion of the MAC result on the MASAR column 102. The total capacitance, C_{TOT}, of the MASAR column 102 is given in Eq. 3. It should again be noted that a zero input cell 112 is not needed if the MASAR column 102 is not performing a full resolution conversion, i.e., where the output of the MASAR column has less than log₂(N_{y}) bits.

FIG. 4B illustrates a second portion (MAC step 2) of the operation of the MASAR column 102 in the MAC mode. In this aspect, the common side of the unit capacitors 206 or bit line is electrically disconnected from the supply, V_{S}, by setting RESET=0. Here again, EM=1, E̅M̅=0. Thus, the total charge, Qₜₒₜ stored in the MASAR column 102 after MAC step 2 remains unchanged. At this point, the bit line is floating in preparation for the ADC conversion of the MAC calculation.

FIG. 4C illustrates a third portion (MAC step 3) of the operation of the MASAR column 102 in the MAC mode. In this aspect, the cell side of the unit capacitors 206 is set to zero potential or 0V. This is done by first ensuring the guess bits (BG[0], BG[1]) are zero, followed by setting, EM=0, E̅M̅=1. At this point, charge redistributes along the entire MASAR column 102 while the total charge, Qₜₒₜ, stored in the MASAR column 102 remains unchanged.

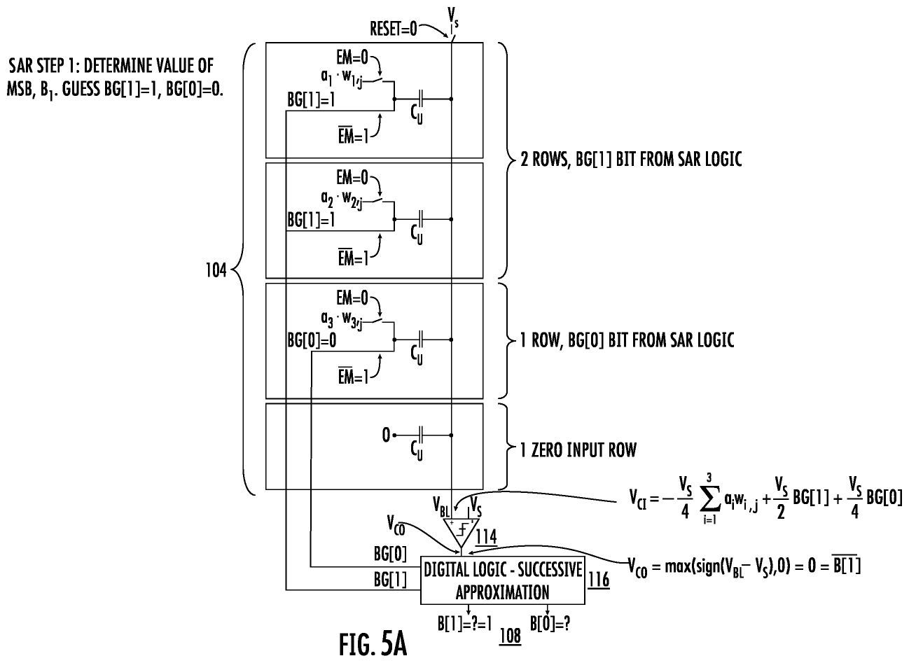

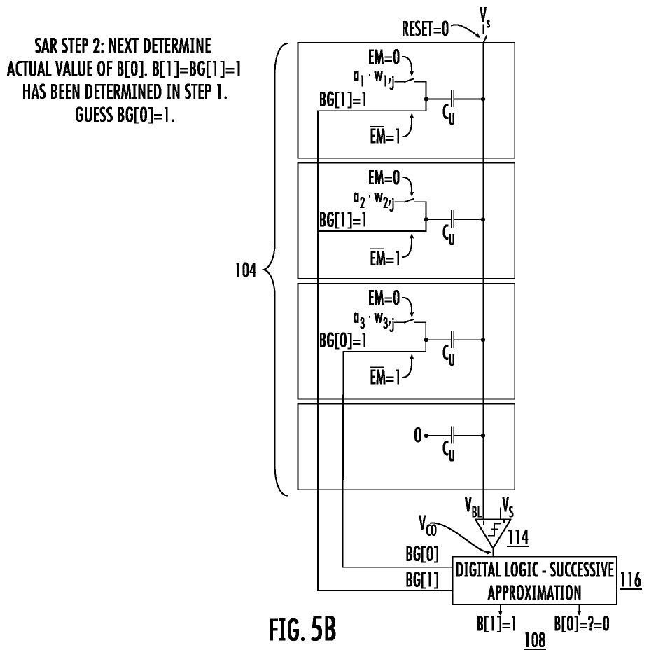

FIG. 5A illustrates a first portion (SAR step 1) of the operation of the MASAR column 102 in the SAR mode. Here, two MASAR cell 104 inputs are connected to BG[1] while one is connected to BG[0]. With these connections, the MASAR column 102 is configured as a 2-bit CDAC 115 and can perform a 2-bit (N=2) conversion or full resolution conversion of its 2^{N} cell MASAR column 102 output. This illustration shows one possible connection of the ADC guess bits to the MASAR cells 104 to enable a N=2 bit analog to digital conversion, and it should be noted that the N_{y} MASAR cells 104 may be connected to the BG[0] and BG[1] in any ordering, so long as any one of the MASAR cells 104 is connected to BG[0] and the two of N_{y} MASAR cells 104 apart from the MASAR cell 104 connected to BG[0] are connected to BG[1].

For this example, the bit line voltage is defined by Eq. 4 and input to the comparator 114 by Eq. 5. Finally, the comparator 114 computes Eq. 6. For purposes of showing how the SAR algorithm operation, the expected result of the MAC is defined by Eq. 7. In this case, the output of the MASAR column 102, for this example, is 2 or B[1]=1, B[0]=0.

$$\begin{matrix}{V}_{BL} = {V}_{s} - \frac{{V}_{s}}{4} {\sum }_{i = 1}^{3} {a}_{i} {w}_{i , j} + \frac{{V}_{s}}{4} {2}^{1} \cdot BG [ 1 ] + \frac{{V}_{s}}{4} {2}^{0} \cdot BG [ 0 ] & Eq . 4 \\ {V}_{CI} = {V}_{BL} - {V}_{s} = - \frac{{V}_{s}}{4} {\sum }_{i = 1}^{{N}_{y} = 3} {a}_{i} {w}_{i , j} + \frac{{V}_{s}}{4} {2}^{1} \cdot BG [ 1 ] + \frac{{V}_{s}}{4} {2}^{0} \cdot BG [ 0 ] & Eq . 5 \\ {V}_{CO} = max ( sign ( {V}_{CI} ) , 0 ) = \{ \begin{matrix}0 , {V}_{CI} <= 0 \\ 1 , {V}_{CI} > 0\end{matrix} & Eq . 6 \\ {\sum }_{i = 1}^{{N}_{y} = 3} {a}_{i} {w}_{i , j} = 2 & Eq . 7\end{matrix}$$

Referring more specifically to the SAR conversion, The SAR conversion (SAR step 1) starts with the SAR logic guessing the most significant bit BG[1]=1, while keeping the least significant bit, BG[0]=0. This results in a comparator 114 input of zero, as shown in Eq., and a comparator 114 output of zero as shown in Eq. Here, the SAR logic assigns B[1]=1.

$$\begin{matrix}{V}_{CI} ( step 1 ) = - \frac{{V}_{s}}{4} 2 + \frac{{V}_{s}}{4} {2}^{1} \cdot ( BG [ 1 ] = 1 ) + \frac{{V}_{s}}{4} {2}^{0} \cdot ( BG [ 0 ] = 0 ) = 0 & Eq . 8 \\ {V}_{CO} ( step 1 ) = max ( sign ( {V}_{CI} ) , 0 ) = 0 = \overline{B [ 1 ]} \to B [ 1 ] = 1 & Eq . 9\end{matrix}$$

FIG. 5B illustrates a second portion (SAR step 2) of the operation of the MASAR column 102 in the SAR mode. Here, the actual value of BG[0] is determined. BG[1] was already determined in SAR step 1.

This portion of the SAR conversion starts with the SAR logic guessing the least significant bit, BG[0]=1. As the most significant bit, BG[1], has been already determined to be 1, that value is not changed. Setting BG[0]=1 results in a comparator 114 input that is greater than zero as shown in Eq. 10. Therefore, the comparator 114 output is one as shown in Eq. 11. The SAR logic assigns B[0]=0. This is the last portion of the SAR computation for this example. The final output of the MASAR column 102 is therefore B[1]=1, B[0]=0, which matches the expected MAC result of 2.

$$\begin{matrix}{V}_{CI} ( step 1 ) = - \frac{{V}_{s}}{4} 2 + \frac{{V}_{s}}{4} {2}^{1} \cdot ( BG [ 1 ] = 1 ) + \frac{{V}_{s}}{4} {2}^{0} \cdot ( BG [ 0 ] = 1 ) = \frac{{V}_{s}}{4} & Eq . 10 \\ {V}_{CO} ( step 1 ) = max ( sign ( {V}_{CI} ) , 0 ) = 1 = \overline{B [ 0 ]} \to B [ 0 ] = 0 & Eq . 11\end{matrix}$$

Thus, a simplified 4-cell MASAR column 102 (N_{BG}=2,N_{y}=3) may accomplish a MAC computation and a SAR analog to digital conversion using the same capacitor 206 array. Note this was done for 1-bit computations which do not require a sign for each MAC product. However, this approach may be extended to signed operations for multibit MACs.

While the aforementioned example utilizes four cells, the MAC mode may be extended to a MASAR column 102 comprised of Nᵣ rows. In this case a Nᵣ row MASAR column 102 may perform N_{y}=Nᵣ−1 one-bit MAC calculations. Thus, the maximum digital value of the MAC output for a MASAR column 102 using Nᵣ−1 rows as inputs is B_{MAX}, as shown in Eq. 12.

$$\begin{matrix}{B}_{MAX} = MAX ( {\sum }_{i = 1}^{{N}_{r} - 1} {a}_{i} \cdot {w}_{ij} ) = {N}_{r} - 1 = {2}^{k} - 1 & Eq . 12 \\ {V}_{BL} = \frac{{Q}_{TOT}}{{C}_{TOT}} = {V}_{s} - \frac{{V}_{s}}{{2}^{N}} {\sum }_{i = 1}^{{N}_{y}} {a}_{i} {w}_{ij} + \frac{{V}_{s}}{{2}^{N}} {\sum }_{n = 0}^{N - 1} {2}^{n} \cdot BG [ n ] & Eq . 13 \\ MAC Output = {B}_{j} [ 0 : N - 1 ] = {\sum }_{i = 1}^{{N}_{y}} {a}_{i} {w}_{i , j} & Eq . 14\end{matrix}$$

The total charge stored on the capacitance of the MASAR column 102 is given earlier by Eq. The bit line voltage (extending the example to the general case) is given by Eq. 13. For the general case the output of the j^{th} MASAR column 102 is a digital output as given by Eq. 14.

As a variation, the addition of an input bias and calibration in MASAR columns 102 may be performed. In some cases, it may be of interest to add input biases, bⱼ, to the MAC calculation. In this case the desired output of the MASAR column 102 is given by Eq. 15:

$$\begin{matrix}MAC Output = {B}_{j} [ 0 : {N}_{BG} - 1 ] = {\sum }_{i = 1}^{{N}_{a}} {a}_{i} {w}_{i , j} + {b}_{j} & Eq . 15 \\ {N}_{a} = {N}_{y} - {N}_{b} - {N}_{c} & Eq . 16\end{matrix}$$

To add these biases N_{b} rows in the MASAR column 102 can be dedicated to the bias input. Since the number of inputs is fixed at N_{y} this reduces the number of possible input activations to Nₐ=N_{y}−N_{b}. For instance, if it is desired to calibrate the SAR ADC, additional N_{c} rows may be dedicated to the addition of calibration of the ADC output. If desired, this may further reduce the quantity of inputs for the MAC, as shown in Eq. 16. It should be noted that while adding bias in MASAR cells 104 may be performed in some approaches, in other approaches the biases may be added to the outputs after the MASAR column 102. This may occur in the digital summation stages, for example (as shown in the FIGS. herein).

Similarly, while the aforementioned example utilizes four cells, the SAR mode may be extended to a MASAR column 102 comprised of Nᵣ rows. Here, the ADC guess bits can be distributed to form an N bit CDAC 115.

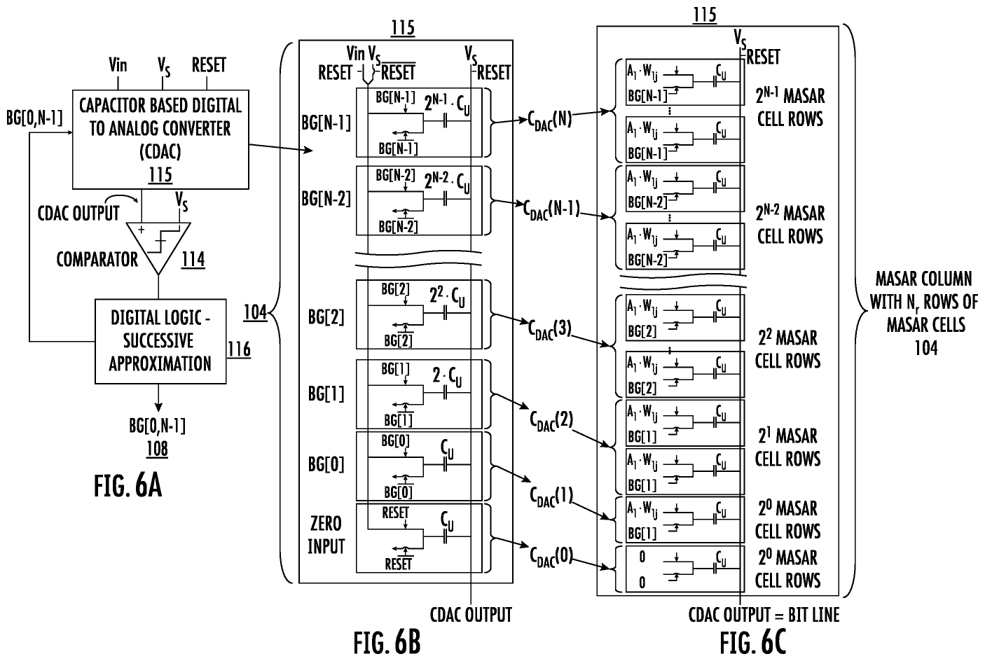

FIG. 6A illustrates a diagram of a SAR ADC with a CDAC 115. In general, a capacitor-based SAR ADC, with a resolution of N bits requires 2^{N} unit capacitors 206 in its capacitor-based digital to analog convertor, CDAC 115.

FIG. 6B illustrates diagram of a SAR ADC N-bit CDAC 115 showing binary scaling of the capacitors 206 and connection of the ADC guess bits, BG[0:N−1]. This shows a simplified binary weighted CDAC 115, which is commonly used in SAR ADCs. The CDAC 115 may include N+1 weight capacitors, CDAC(n). Each weight capacitor in the CDAC 115 ranges from Cᵤ to 2^{N-1}. Cᵤ, as shown in Eq. 17. During ADC conversion, the binary weighted capacitors of the C_{DAC}(n=0 . . . N) are controlled by the corresponding ADC guess bit BG[n−1] for n>0.

FIG. 6C illustrates diagram of a MASAR column 102 with Nᵣ rows of MASAR cells 104. As shown, the illustration shows how blocks of the MASAR cells 104 are connected to the ADC guess bits to enable ADC conversion of the charge-based MAC result. Here, it is shown how the rows of MASAR cells 104 in the MASAR column 102 can be arranged to form the binary weighted capacitors in a SAR ADC. For instance, it requires 2^{N-1} rows of MASAR cells 104 to implement the largest capacitance in the CDAC 115, C_{DAC}(n=N). Thus, a MASAR column 102 with 2^{N} MASAR cells 104 can be configured to perform a SAR ADC conversion up to N bits.

$$\begin{matrix}{C}_{DAC} ( n ) = \{ \begin{matrix}{C}_{u} , & n = 0 \\ {2}^{n - 1} \cdot {C}_{u} , & n = 1 ⋯ N\end{matrix} & Eq . 17 \\ k = {log}_{2} {N}_{r} & Eq . 18\end{matrix}$$

Accordingly, a MASAR column 102 may be configured as an SAR ADC with a maximum ADC resolution or max number of bits, N_{BG}=k (for 2's complement) and, N_{BG}=k+1 for signed integer computation. While optional, it is assumed one row in all MASAR columns 102 is the row of zero input cells 112. Doing so ensures the SAR ADC including the rows of MASAR cells 104 can perform a full resolution conversion of the MAC result.

One key aspect of the SAR computation and MASAR concept is the routing of the ADC guess bits, BG[n], to the MASAR cells 104. An example MASAR column 102 may be used to demonstrate different options for setting the SAR ADC conversion resolution by changing how we configure the MASAR column 102 ADC guess bits.

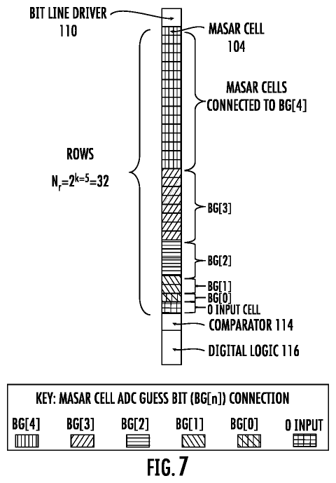

FIG. 7 illustrates an example MASAR column 102 with 32 rows. For this example, Nᵣ=32, k=5; therefore, maximum SAR ADC resolution for this column is N_{BG}=k=5 bits. Here, one possible configuration of ADC guess bits BG[0:4] connections for enabling a 5-bit SAR ADC conversion. In general, full ADC resolution conversion of a MAC result with a MASAR column 102 having Nᵣ=2^{k} rows with N_{y}_{_{MAX}} inputs, k bits are required. This ensures (ideally) no loss of information. However, in some cases it is not necessary to convert the result with the full resolution but with less than k bits. This can be done by reconfiguring the connection of the ADC guess bits in the MASAR column 102.

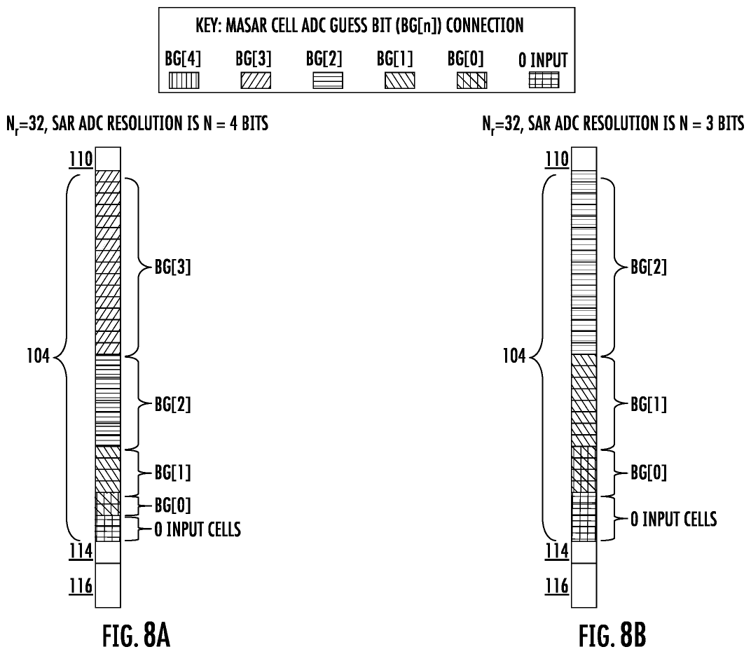

FIG. 8A illustrates an example of ADC guess bit connections for quantization to N=4 bits of a 5-bit MAC result. Note, there is no BG[4] bit. Also, there are now two input cells that have zero input during the SAR ADC conversion. One of these has an input during the MAC calculation mode, while the other is the zero input cell 112.

FIG. 8B illustrates an example of the ADC guess bit connections for quantization to N_{BG}=3 bits of a 5-bit MAC result. In general, the configuration of a MASAR columns 102 ADC guess bit inputs can be used to enable quantization of the N_{BG}=k bit MAC result down to 1 bit.

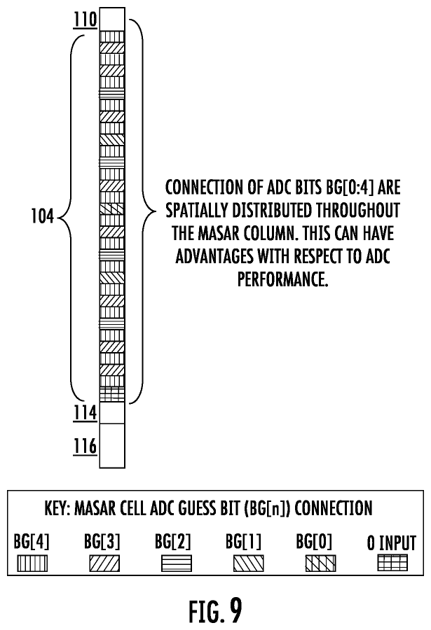

FIG. 9 illustrates an example of spatial distribution of ADC guess bits for a MASAR column 102 with 32 rows. As noted above, the configuration of ADC guess bits may be used to change ADC resolution. Another aspect to consider is how capacitor matching affects quantization accuracy. For SAR ADCs there may be layout methods that can be used to reduce the effect of capacitor mismatch by spatially distributing the capacitors of the SAR ADC and as enumerated in Eq. 17. This approach may be extended to a MASAR column 102 by distributing the connections of the ADC guess bits. An example of this type of spatial distribution of ADC guess bits is shown, where the bits that make up the different guess bits are spatially randomized across the MASAR column 102.

It should be noted that these SAR ADC conversion modes assume MASAR columns 102 configured as a binary CDAC 115. In other words, the capacitors are sized such that they are binarily weighted, as shown in Eq. 17. The choice of binary weighting may dictate how the ADC guess bits are distributed to control the individual MASAR cells 104 in the previous sections. However, there are alternatives to binary weighting. For example, a SAR ADC may be developed with non-binary split-capacitor arrays, which can be implemented as well in the MASAR columns 102. Use of a MASAR column 102 for such applications may provide even more compact architectures and/or lower energy implementations as compared to other designs of SAR ADC.

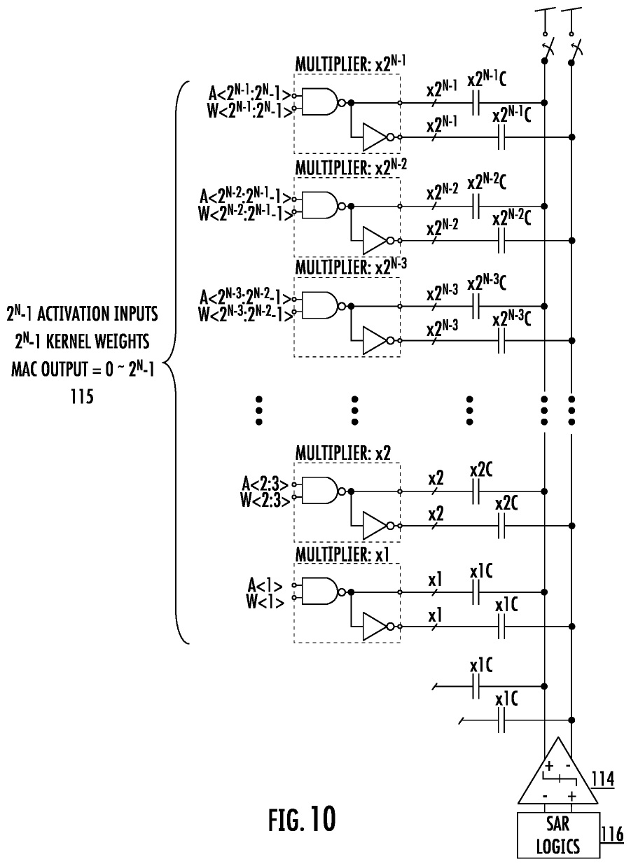

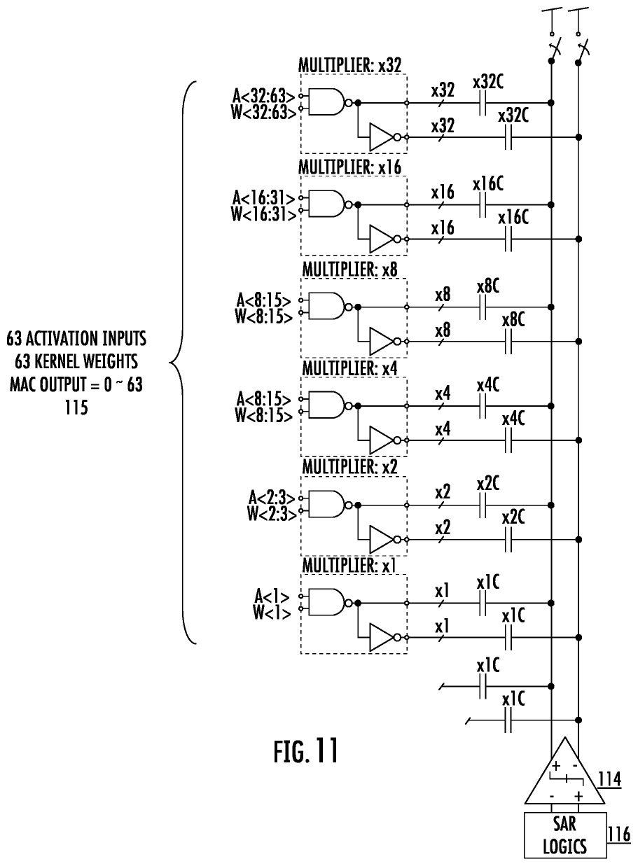

FIG. 10 illustrates an example MASAR column 102 of arbitrary number of rows, Nᵣ=2^{N}. As shown, the MASAR column 102 includes 2^{N}−1 activation inputs (digital inputs 106), and 2^{N}−1 weights (wᵢ). The MASAR column 102 may produce an output value in a range from 0 to 2^{N}−1. FIG. 11 illustrates an example MASAR column 102 of size N=6. As shown, the MASAR column 102 includes 2⁶−1=63 activation inputs (digital inputs 106), and 63 weights (wᵢ). Such a MASAR column 102 may produce an output value in a range from 0 to 63.

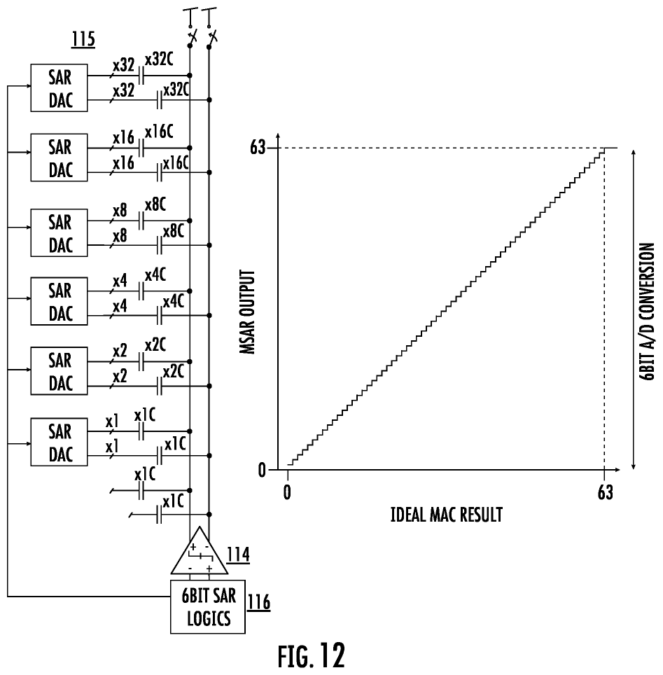

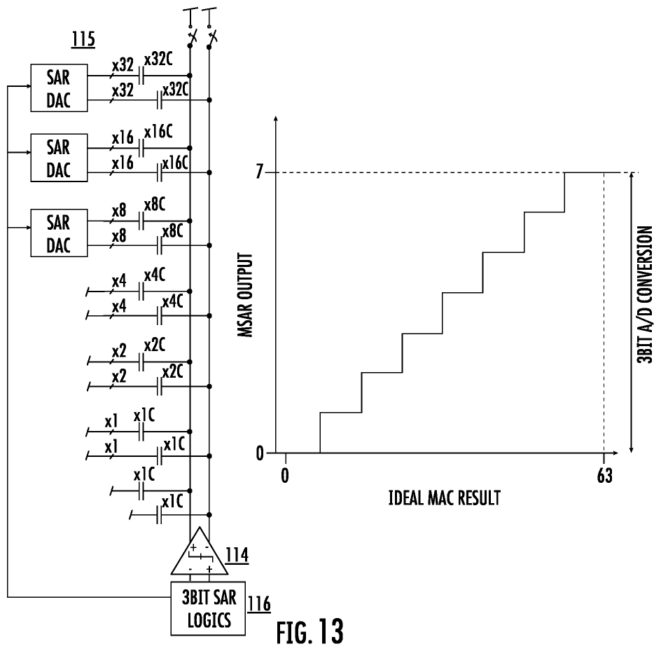

FIG. 12 illustrates an example of the MASAR column 102 in combination with a graph of the ADC output values. As shown, the output values of the MASAR column 102 are shown in the Y-Axis vs each of the possible results of the multiplications performed by the MASAR cells 104 of the MASAR column 102. As shown, each result maps to its corresponding output value. In this configuration of ADC, the MASAR column 102 performs an M-bit conversion for the 2^{N}−1 values, where M=N. In other words, the MASAR column 102 performs a full conversion.

For some applications, however, it may be desirable to utilize a subset of possible values that may be available through use of the MASAR column 102. For instance, in some cases less precision may be desired. In such a case the LSB may not be used. Or, in other cases conversion may be desired for a subset of ranges of the values, with values below the range of interest being set to a minimum and values above the range of interest begin set to a maximum. As discussed above abstractly with respect to FIG. 8, a MASAR column 102 with a maximum resolution may be configured to use a lower resolution (as some examples, a 5 bit MASAR column 102 may be configured to use a resolution of 4 or 3 bits). FIG. 13 illustrates another example of the concept introduced in FIGS. 8A-B. In this case, FIG. 13 shows in detail how a 6-bit maximum resolution MASAR column 102 may be configured to 3-bit operation.

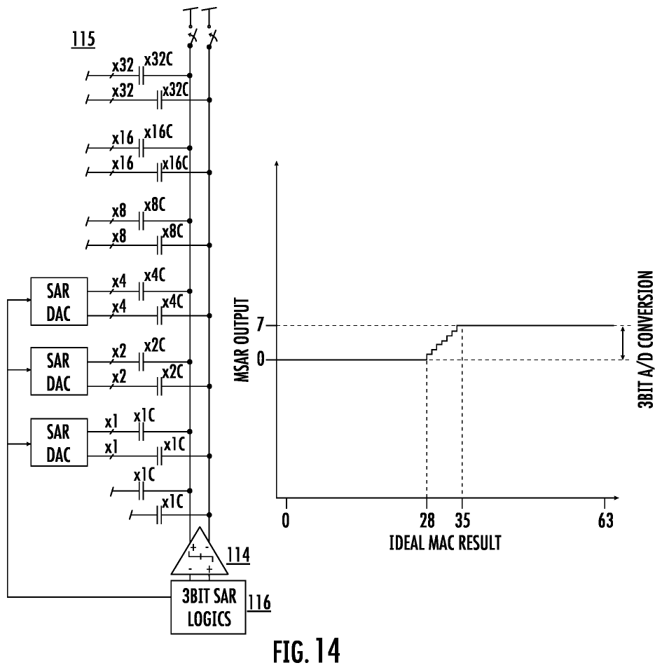

FIGS. 14-21 show this concept may be extended to zoom in. An A/D conversion of a subset of interest may be referred to as a zoom ADC conversion. Which bits are used determines the range of values, and how the unused bits are tied to the SAR ADC may be used to affect the shift of where the range of values may fall. Advantageously, by configuring the mapping of the unit capacitors 206 to the SAR DAC, configurable output mappings of the and offset range of values may be performed.

Referring more specifically to FIG. 13, the figures illustrates an example coarse-precision mapping of the output values of the MASAR column 102. Here, an approximate conversion is performed. In this configuration of ADC, the MASAR column 102 performs an M-bit conversion for the 2^{N}−1 values, where M<N. In this example, N=6, M=3. As shown, the LSB=2^{N-M}=2³=8 code values. Additionally, the MASAR column 102 is wired such that only the MSB M bits of the output of the MASAR column 102 are considered. The three least significant bits are simply not considered in the ADC conversion and may be discarded. Such an approach provides values across the range of the 2^{N}, but lacking precision.

FIG. 14 illustrates a first example fine-precision mapping of a subset of the output values of the MASAR column 102. Here, an M-bit conversion is again being performed for 3 bits of the 6 bits, but instead of the LSB being 3 times larger than the minimum (FIG. 13), the LSB remains the same size as the example in FIG. 12. In this case 3 bits are being used (here the 4-, 2-, and 1-bit positions for a range of 4+2+1=7). The 3 MSBs (here, the 32-, 16-, and 8-bit positions) are wired to always high, and the corresponding differential of the 3 MSBs are also wired to high. Effectively, this causes the output to be shifted by an offset of

$$\frac{( 32 + 16 + 8 )}{2} = 28.$$

Accordingly, the resultant mapping is from a low value of 28 to a high value of 28+7 or 35, based on the values of the 3 LSBs.

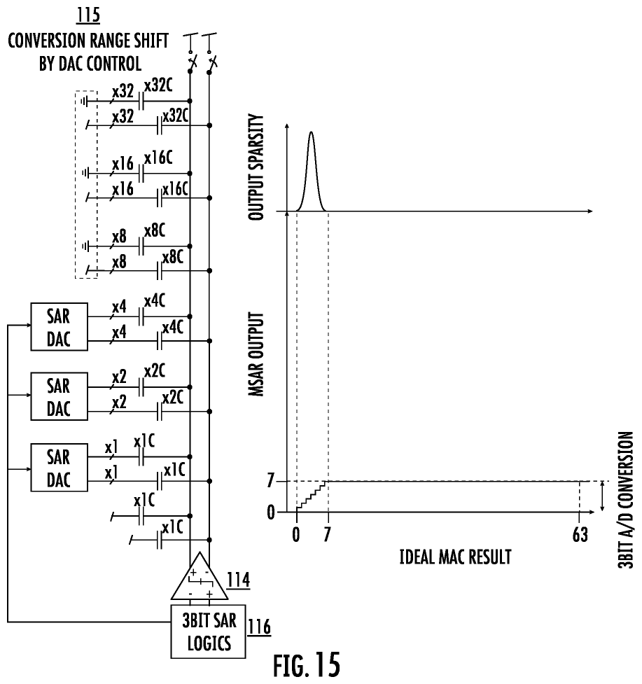

FIG. 15 illustrates a second example fine-precision mapping of a subset of the output values of the MASAR column 102. Here, an M-bit conversion is again being performed for 3 bits of the 6 bits, again with the LSB 3 bits. However, the 3 MSBs are wired to always low, and the corresponding differential of the 3 MSBs are wired to the high. Effectively, this causes the conversion range to remain unshifted. Accordingly, the resultant mapping is from a low value of 0 to a high value of 7, based on the values of the 3 LSBs.

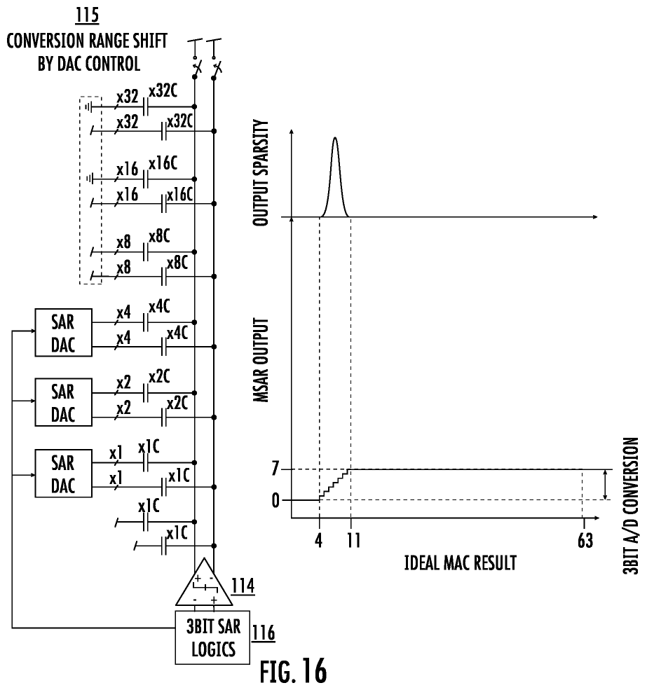

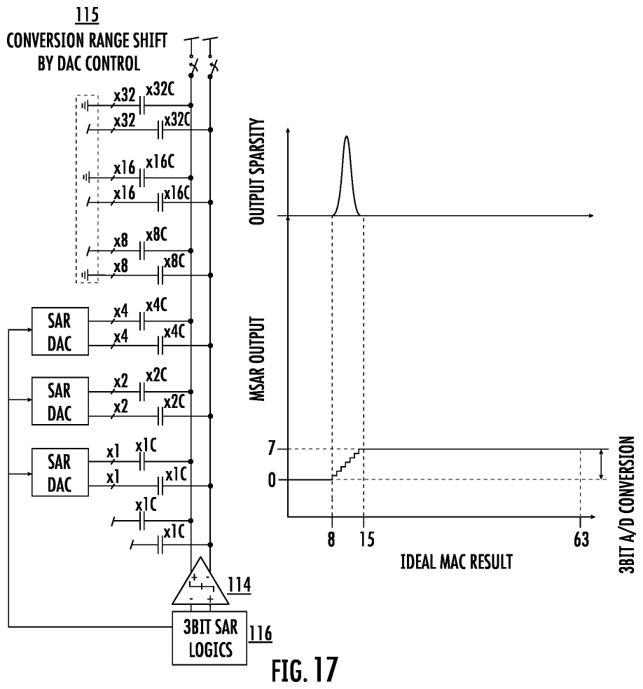

FIG. 16 illustrates a third example fine-precision mapping of a subset of the output values of the MASAR column 102. Here, an M-bit conversion is again being performed for 3 bits of the 6 bits, again with the LSB 3 bits. However, the 2 MSBs are wired to always low, and the corresponding differential of the 3 MSBs are wired to the high, but the 3rd MSB (the 8 bit) is wired to always high, and its corresponding differential also to always high. Effectively, this causes the output to be shifted by an offset of 8/2=4. Accordingly, the resultant mapping is from a low value of 4 to a high value of 4+7=11, based on the values of the 3 LSBs.

FIG. 17 illustrates a fourth example fine-precision mapping of a subset of the output values of the MASAR column 102. Here, an M-bit conversion is again being performed for 3 bits of the 6 bits, again with the LSB 3 bits. However, the 2 MSBs are wired to always low, and the corresponding differential of the 3 MSBs are wired to the high, but the 3^{rd} MSB (the 8 bit) is wired to always high, and its corresponding differential to always low. Effectively, this causes the output to be shifted by an offset of 8. Accordingly, the resultant mapping is from a low value of 8 to a high value of 8+7=15, based on the values of the 3 LSBs.

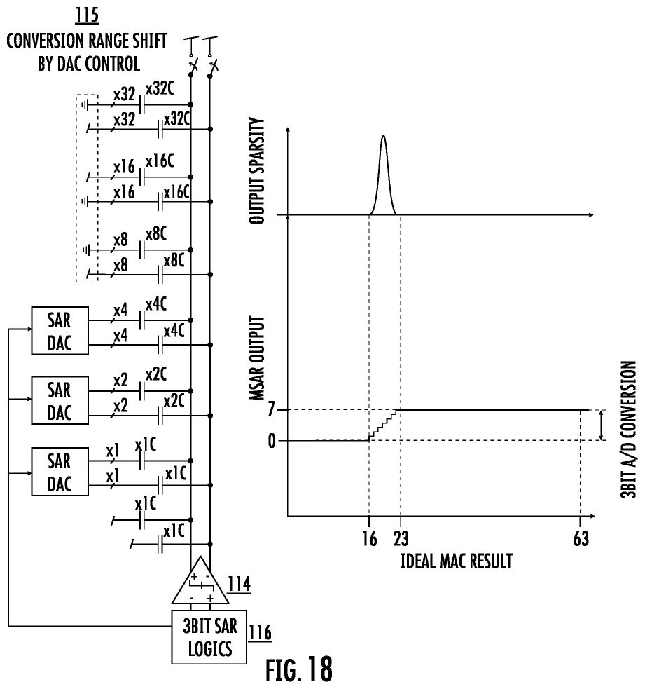

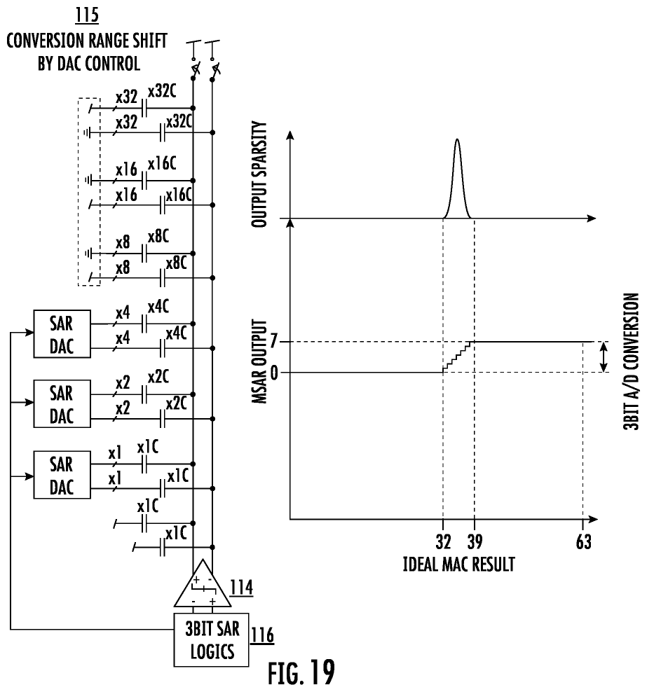

FIG. 18 illustrates a fifth example fine-precision mapping of a subset of the output values of the MASAR column 102. Here, an M-bit conversion is again being performed for 3 bits of the 6 bits, again with the LSB 3 bits. However, the 32- and 8-bit MSBs are wired to always low, and the corresponding differential to high, but the 2^{nd} MSB (the 16-bit) is wired to always high, and its corresponding differential to always low. Effectively, this causes the output to be shifted by an offset of 16. Accordingly, the resultant mapping is from a low value of 16 to a high value of 16+7=23, based on the values of the 3 LSBs.

FIG. 19 illustrates a sixth example fine-precision mapping of a subset of the output values of the MASAR column 102. Here, an M-bit conversion is again being performed for 3 bits of the 6 bits, again with the LSB 3 bits. The 32-bit MSBs is wired to always high, and the corresponding differential to low, but the 2^{nd} and 3^{rd} MSB (the 16-bit and 8-bits) are wired to always low, and with corresponding differential to always high. Effectively, this causes the output to be shifted by an offset of 32. Accordingly, the resultant mapping is from a low value of 32 to a high value of 32+7=39, based on the values of the 3 LSBs.

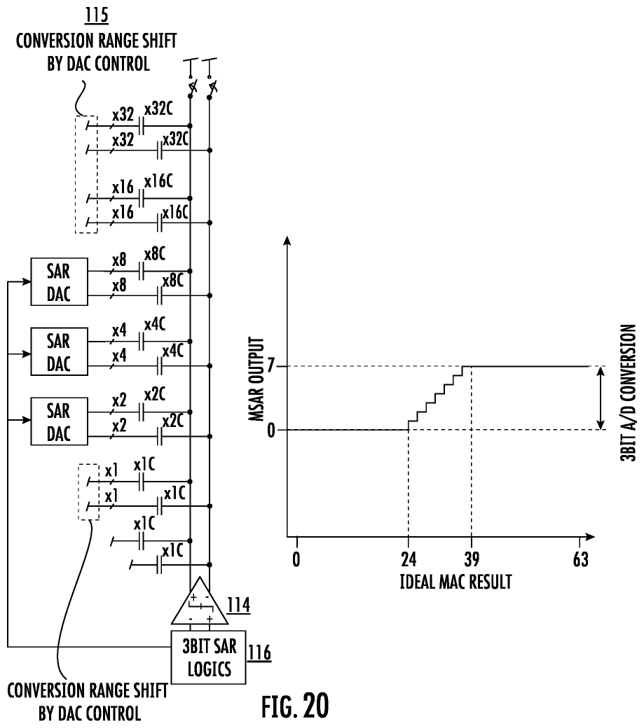

FIG. 20 illustrates an example mid-precision shifted mapping of a subset of the output values of the MASAR column 102. Here, an M-bit conversion is again being performed for 3 bits of the 6 bits, but this time with the 8-, 4- and 2-bits (for a range of 8+4+2=14). The 32-, 16- and 1-bits are wired to always high, and the corresponding differential to high. Effectively, this causes the output to be shifted by an offset of

$$\frac{32 + 16 + 1}{2} = 24.$$

Accordingly, the resultant mapping is from a low value of 24 to a high value of 24+14=46, with a step size of 2, based on the values of the 3 utilized bits (the 8-, 4- and 2-bits).

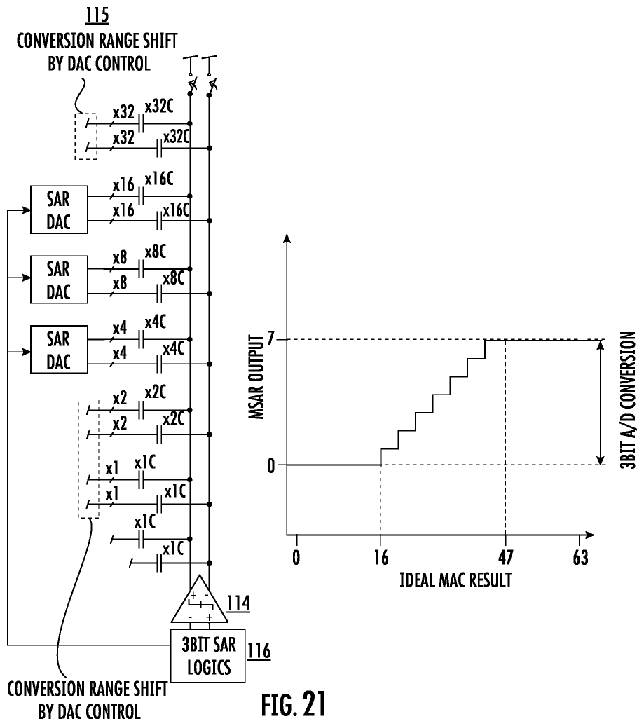

FIG. 21 illustrates an alternate example mid-precision shifted mapping of a subset of the output values of the MASAR column 102. Here, an M-bit conversion is again being performed for 3 bits of the 6 bits, but this time with the 16-, 8- and 4-bits (for a range of 16+8+4=28). The 32-, 2- and 1-bits are wired to always high, and the corresponding differential to high. Effectively, this causes the output to be shifted by an offset of 16. Accordingly, the resultant mapping is from a low value of 16 to a high value of 47, with a step size of 4, based on the values of the 3 utilized bits (the 16-, 8- and 4-bits).

Thus, by configuring the mapping of the unit capacitors 206 to the SAR DAC, configurable output mappings of the and offset range of values may be performed. It should also be noted that the number of inputs is not limited to being need to 2^{N}-1. Indeed, any number of inputs N>2^{M} may be possible with approximate conversion.

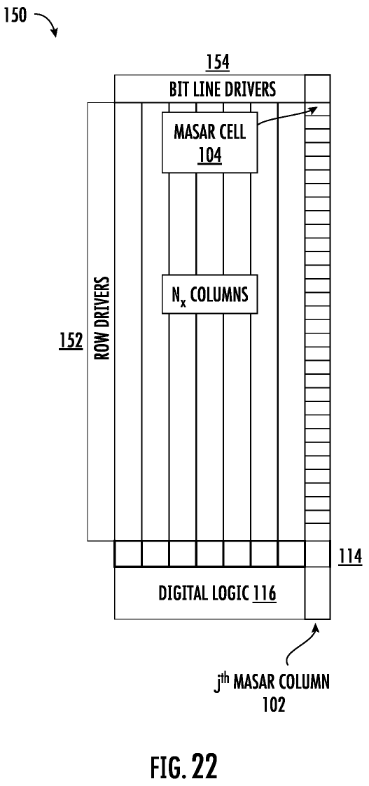

FIG. 22 illustrates an example MASAR array 150 of a group of MASAR columns 102. The illustrated MASAR Array 150 includes Nₓ MASAR columns 102. Each column may include j elements, as noted in the previous MASAR column 102 examples. The MASAR array 150 may further include bit line drivers 110 and digital logic 116 as mentioned above, as well as row drivers 152. The MASAR array 150 may be used to accelerate large scale multibit precision parallel MAC calculations.

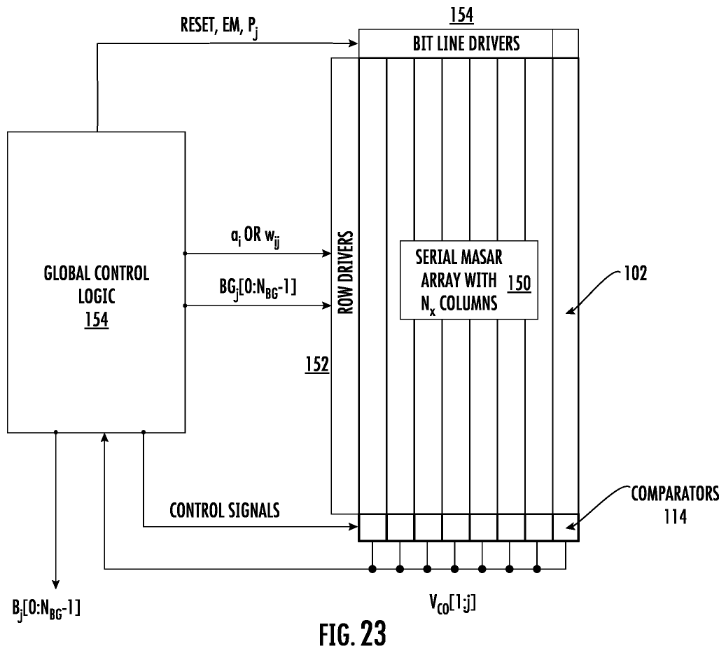

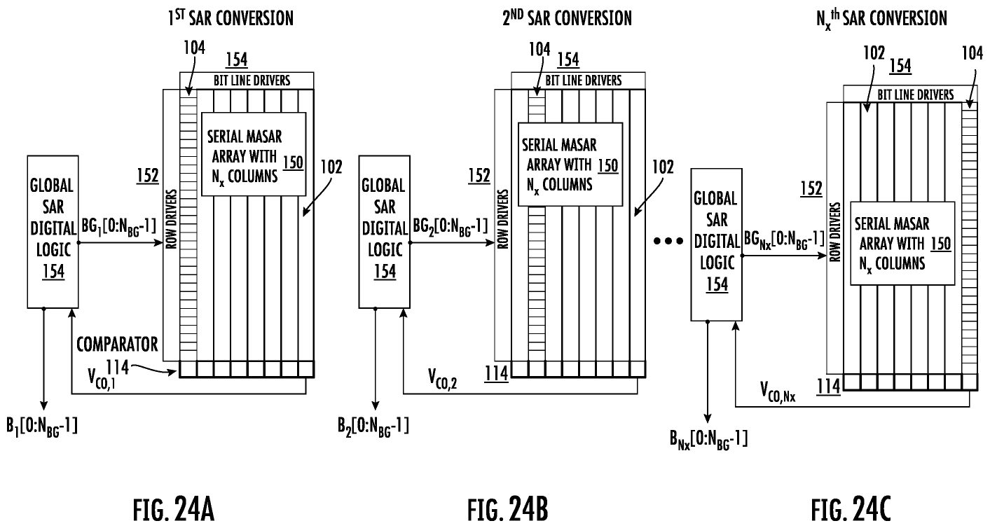

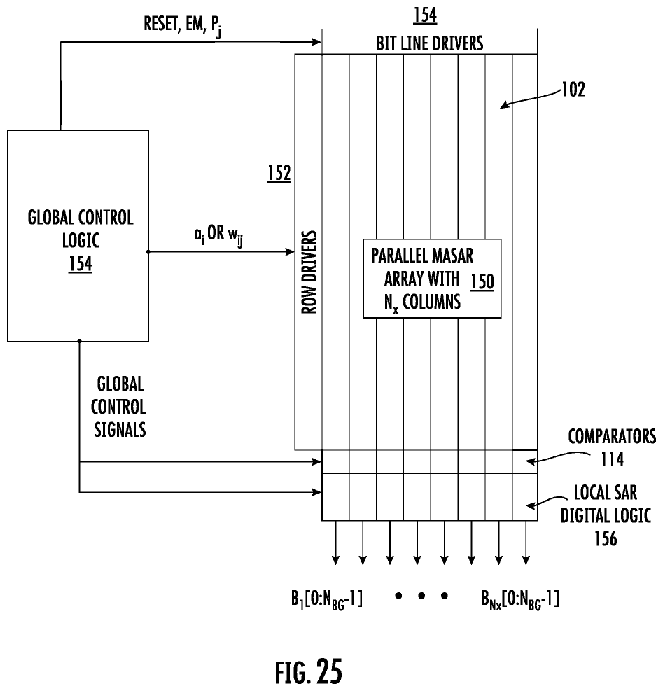

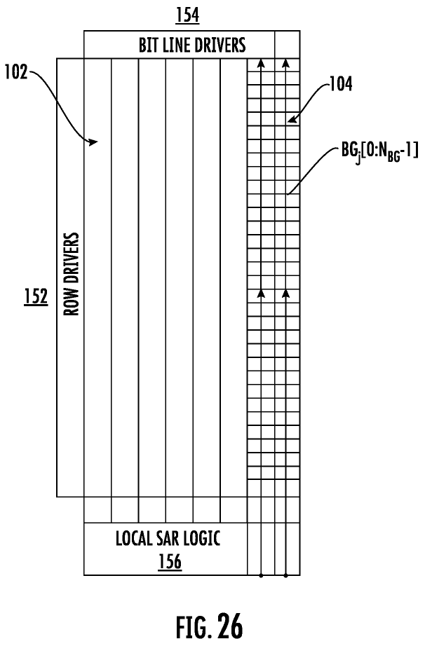

Serial and parallel SAR architectures for the MASAR columns 102 and MASAR arrays 150 may be utilized. FIGS. 23, 24A, 24B, and 24C illustrate MASAR arrays 150 in a serial configuration. FIGS. 25-26 illustrate MASAR arrays 150 in a parallel configuration.

For a serial SAR MASAR array 150 the MAC calculation occurs in parallel, however, the SAR ADC conversion of the MAC results occur in a serial fashion. The ADC conversion occurs in each MASAR column 102 one at a time. The advantage of this architecture is that the SAR logic can be global and does not need to be in each MASAR column 102. This results in an area savings for the MASAR array 150. The disadvantage is that throughput or the speed of the MAC calculation is reduced. However, for some applications the tradeoff between area and speed is advantageous.

FIG. 23 illustrates an example MASAR array 150 in a serial configuration with digital logic 116. Here, global digital logic 154 may be used orchestrate the SAR conversion for each column, j=1, 2, . . . , Nₓ, thereby determining the N^{th} bit, Bⱼ[0:N_{BG}−1], output for each column. In this case, the MASAR columns 102 have a one-bit output coming from the comparator 114 output, V_{CO,j}, which the global digital logic 154 may use as the input for the SAR ADC algorithm. The global digital logic 154 may also apply the ADC guess signals, BGⱼ[0:N_{BG}−1], to the row driver 152 during the SAR modes. Finally, the digital logic 116 may provide the digital MAC output, B; [0:N_{BG}−1], for each of the j rows in the serial array.

Additionally, the global digital logic 154 may provide control signals for the different modes of the MASAR array 150. These modes are described in Table 2. For instance, the digital logic 116 may apply input activations, at, to the row driver 152 in the MAC mode and weight values, wᵢⱼ, for programming the SRAM 202 weight memories in the weight programming mode.

FIGS. 24A-C collectively shows how each column output is converted to digital in a serial fashion. FIG. 24A illustrates a first SAR ADC conversion of the first bit from the first MASAR column 102 of the MASAR array 150. FIG. 24B illustrates a second SAR ADC conversion of the second bit from the second MASAR column 102 of the MASAR array 150. This process may continue sequentially until conversion of the last MASAR column 102. FIG. 24C shows the conversion of the N^{th} bit from the N^{th} MASAR column 102 of the MASAR array 150.

FIG. 25 illustrates an example MASAR array 150 in a parallel configuration with digital logic 116. For parallel SAR MASAR arrays 150, the SAR ADC conversion occurs in parallel. Thus, all outputs of the MASAR columns 102 may be available at the same time. Each MASAR column 102 has a N_{BG}-bit output, Bⱼ[0:N_{BG}−1]. The advantage of this architecture is throughput or speed. The cost is the extra circuitry and area required to locate the SAR ADC digital logic 116 in each MASAR column 102. However, if throughput is important, the tradeoff of increased area for increased may be advantageous.

The global digital logic 154 may be used to orchestrate top level functions of the parallel array, for providing control signals for the different modes of the MASAR array 150, as discussed in Table 2. For example, the global digital logic 154 may apply input activations, aᵢ, to the row drivers 152 in the MAC mode, and may provide provides weight memory values, wᵢⱼ, for programming the SRAM 202 in the weight programming mode. The digital logic 116 may also controls the timing of the array signals.

Unlike the serial MASAR array 150, however, the global digital logic 154 in the parallel MASAR array 150 may not apply the ADC guess signals, BGⱼ[0:N_{BG}−1], to the row driver 152 during the SAR modes. Instead, this may be done by local SAR logic 156 in each MASAR column 102, which is routed through the MASAR column 102 to each MASAR cell 104.

FIG. 26 illustrates an example MASAR array 150 in a parallel configuration showing the routing of ADC guess signals BGᵢ[0:N_{BG}−1]. As shown, the guess signals are routed through the MASAR column 102 from the local SAR logic 156 to the MASAR cells 104 in each MASAR column 102.

Thus, MASAR columns 102 and MASAR arrays 150 which perform 1-bit MAC computations may be utilized in serial or parallel configurations. These computations may include a summation of products of 1-bit weights and activations. Additionally, MASAR columns 102 and MASAR arrays 150 may be used to perform multi-bit MAC computations. In such examples, the weights and activations can be >1-bit in precision.

Multibit digital multiplications may be decomposed into individual units, which may be implemented using MASAR columns 102. A product of Nₚ bit precision weights and activations may accordingly be accomplished. An example of 4-bit signed integer (Nₚ=4-bit) activations and weights is defined as shown in Eq. 19 and Eq. 20. The multibit activations and weights may be represented by single bits having different significance, l. For instance, Aᵢ can be represented by the 1-bit values, aᵢₗ, and Wᵢₗ by the 1-bit values wᵢ. The most significant bits are the sign bits, aᵢ₃, wᵢ₃. These may be used to calculate the sign bit for the overall product, as given by Eq. 21. Note, for simplicity of notation, that the column index j for the weights is omitted in these examples.

$$\begin{matrix}{A}_{i} = {( - 1 )}^{{a}_{i 3}} \cdot ( {2}^{2} {a}_{i 2} + {2}^{1} {a}_{i 1} + {2}^{0} {a}_{i 0} ) & Eq . 19 \\ {W}_{i} = {( - 1 )}^{{w}_{i 3}} \cdot ( {2}^{2} {w}_{i 2} + {2}^{1} {w}_{i 1} + {2}^{0} {w}_{i 0} ) & Eq . 20 \\ {S}_{i} = {( - 1 )}^{{w}_{i 3} ⊕ {a}_{i 3}} & Eq . 21\end{matrix}$$

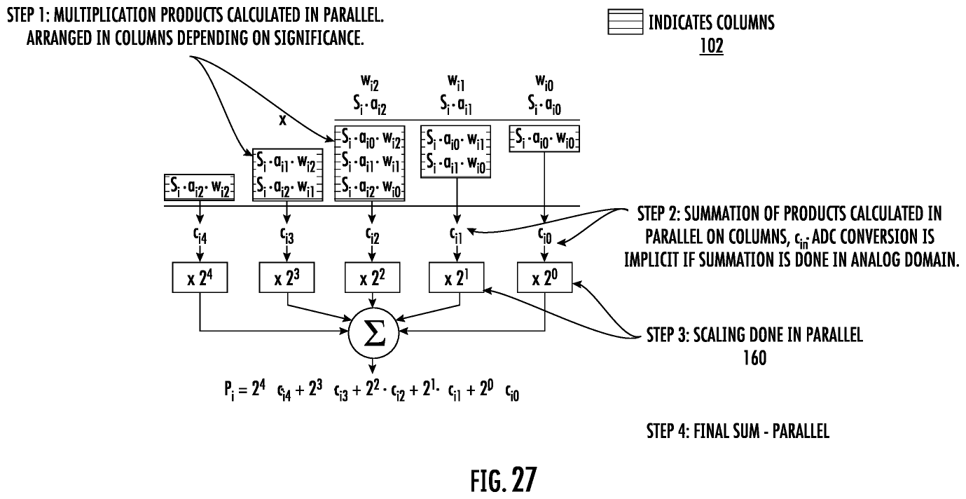

FIG. 27 illustrates an example of 4-bit signed integer multiplication in a parallel case. As shown, the 4-bit computation of the product, Pᵢ=Aᵢ·Wᵢ, may be broken down into multiple parallel operations. Each of these operations may include multiple parallel operations (1-bit multiplication, summation, scaling, summation). In the example implementation, these operations include performing 1-bit digital multiplication, summation in charge, and conversion to digital. These operations may be performed as follows:
1. All 1-bit digital numbers are multiplied (in digital) to form products. E.g., Sᵢ·aᵢ₀·wᵢ₀. The sign bit, Sᵢ, determines the sign of the result. The products have a value of −1, 0 or 1.
2. All products in columns are summed (in columns based on significance). The summation is performed in analog via charge summation. The summed results are converted to digital via ADC conversion resulting in column outputs, cᵢ₀ to cᵢ₄.
3. All column summations are scaled that by significance digitally. Scaling in this case are simple bit shifts. For example, cᵢ₁=Sᵢ·aᵢ₀·wᵢ₁+Sᵢ·aᵢ₀·wᵢ₁, is scaled by 2¹. This requires a left shift of one bit of the digital result cᵢ₁.
4. All scaled column summations are digitally summed to obtain the final product, Pᵢ.

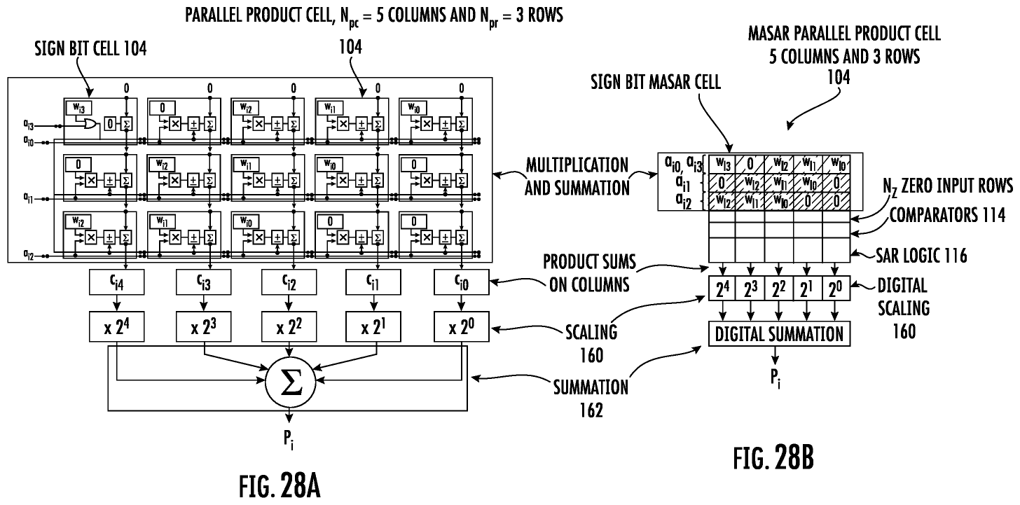

FIGS. 28A-B collectively illustrate an architecture that implements the parallel multiplication function shown in FIG. 27. FIG. 28A illustrates a parallel 4-bit signed integer multiplier. FIG. 28B illustrates a MASAR array 150 implementing the parallel 4-bit signed integer multiplier of FIG. 28A. The architecture includes a product cell with 3 rows and 5 columns followed by scaling and summation.

Each cell in FIG. 28A contains a weight memory, e.g., a SRAM 202, that is programmed as shown. The sign of each cells output in FIG. 28A is controlled by the sign bit, Sᵢ. Sᵢ is computed in the “Sign bit Cell” at the top right of the array. The sign bit is routed from the sign bit cell to the other cells. While this example is shown as signed, a similar computation may be performed for two's complement values as well.

FIG. 28B illustrates a MASAR array 150 implementation of the parallel multibit multiplier 204. In this case, a MASAR cell 104 performs the 1-bit products and summation (in the charge domain). Then each MASAR column 102 is used as a SAR ADC (2-bit in this example) to convert the sums from charge to digital using similar techniques to those described with respect to single bit computations. After that, scaling may be performed digitally, e.g., via bit shifts 160. The final summation 162, in FIG. 28B, is also done digitally.

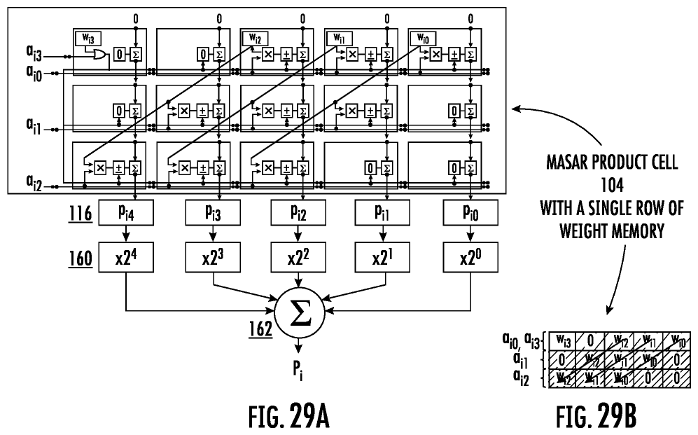

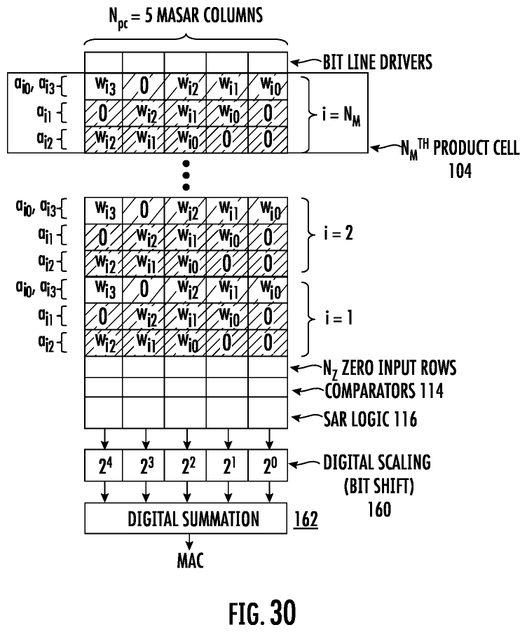

FIG. 29A illustrates a parallel 4-bit signed integer multiplier. The multiplier includes 5 MASAR columns 102 for each product sum and 3 rows of simplified MASAR cells 104. The sign bit, Sᵢ, is distributed to all the MASAR cells 104. In the illustrated example, only one row of cells has a weight memory SRAM 202. In this case the weight values may be routed to the other cells (as shown in the diagonals). FIG. 29B illustrates a product representation of the diagram of FIG. 29A. Here, the routing is shown in the diagonal arrows.

The architecture shown in FIGS. 27, 28A-28B, and 29A-29B implements a single 4-bit product. To implement multiple products in parallel, additional MASAR cells 104 may be utilized.

FIG. 30 illustrates an example of a single channel/kernel multibit MASAR array 150 for calculating N_{M} 4-bit signed integer MACs.

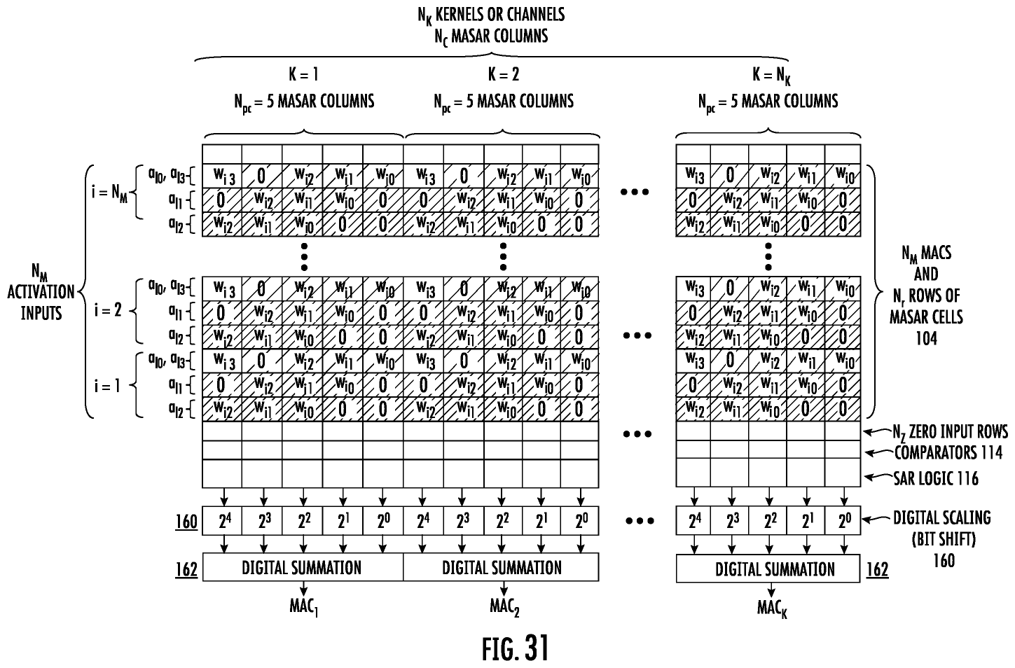

FIG. 31 illustrates an example of multiple channels/kernels in parallel to accommodate larger parallel computations. In FIG. 31, there are N_{K} channels. Each channel can compute N_{M} MACs with 4-bit precision, in parallel. Mathematically this is shown by Eq. 22 as follows:

$${MAC}_{K} = {\sum }_{i = 1}^{{N}_{M}} {A}_{i} \cdot {W}_{i , K} \qquad Eq . 22$$

While previous examples have been with Nₚ=4-bit signed integers, this architecture can be scaled to precisions that are larger or smaller than 4-bits. This involves scaling the number of rows, Nₚᵣ, and columns, N_{pc}, of the product cells, as shown in Eq. 23 and Eq. 24.

$$\begin{matrix}{N}_{pr} = {N}_{p} - 1 & Eq . 23 \\ {N}_{pc} = 2 \cdot {N}_{p} - 3 & Eq . 24\end{matrix}$$

The relationship between the total number of rows, Nᵣ, in the MASAR column 102 the number of MACs, N_{M}, and number of zero input rows, N_{Z}, can be determined with Eq. and Eq.

$$\begin{matrix}{N}_{M} = floor ( \frac{{N}_{r}}{{N}_{p} - 1} ) & Eq . 25 \\ {N}_{z} = {N}_{r} - {N}_{M} \cdot ( {N}_{p} - 1 ) & Eq . 26\end{matrix}$$

It is assumed here the number of rows, Nᵣ, must be a power of 2 to enable using of a binary weighted capacitor DAC in each MASAR column 102. To give an example let Nᵣ=2^{k}=256 (k=8) and Nₚ=4 bits. In this case, Nₚᵣ=3, N_{pc}=5, N_{Z}=1, and N_{M}=85 can be calculated from the equations above. For this example, a 256-row by 5-column MASAR array 150 can compute 85 parallel MACs with 4-bit precision. Note zero input rows are added to insure there are 2^{k} MASAR cells 104 in each MASAR column 102. This is required since each MASAR column 102 is also an k=8-bit SAR ADC. In another example, a 256-row by 13-column, 8-bit precision MASAR array 150 can compute N_{M}=36 MACs. For the 8-bit case: Nₚᵣ=7, N_{pc}=13, and N_{Z}=4.

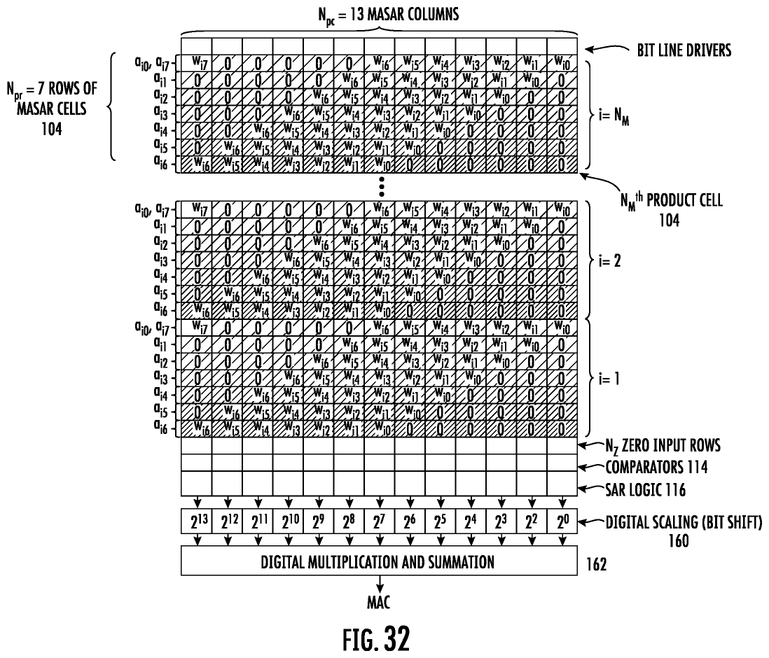

FIG. 32 illustrates an example of a single channel 8-bit signed integer parallel MASAR array 150 accelerator. As was shown for the 4-bit case in FIG. 30, multiple 8-bit precision channels may be placed in parallel. It is notable that adding channels does not change the ADC resolution for each MASAR column 102. However, increasing N_{M} or Nᵣ may increase the required resolution. Also, the number of zero input rows is increased to 4 in the 8-bit case. In this case, the zero input rows can potentially be used for other purposes such as input biases or calibration. Significantly, if other capacitor DAC approaches are used extra zero input rows may not be required.

While parallel multibit architectures improve speed of computation, serial architectures are more compact. In this section we describe how to decompose multibit digital multiplications into serial computations which enable smaller multibit MASAR array 150 accelerators.

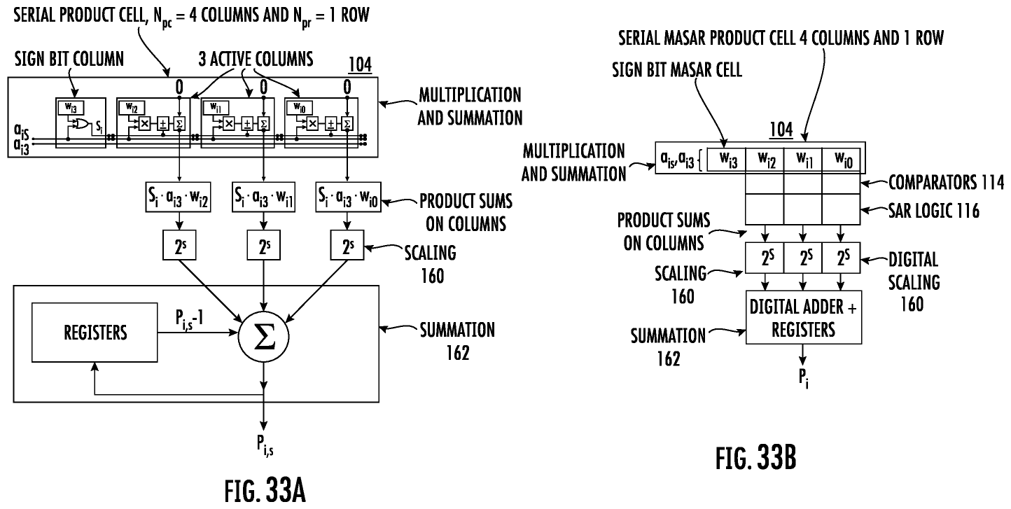

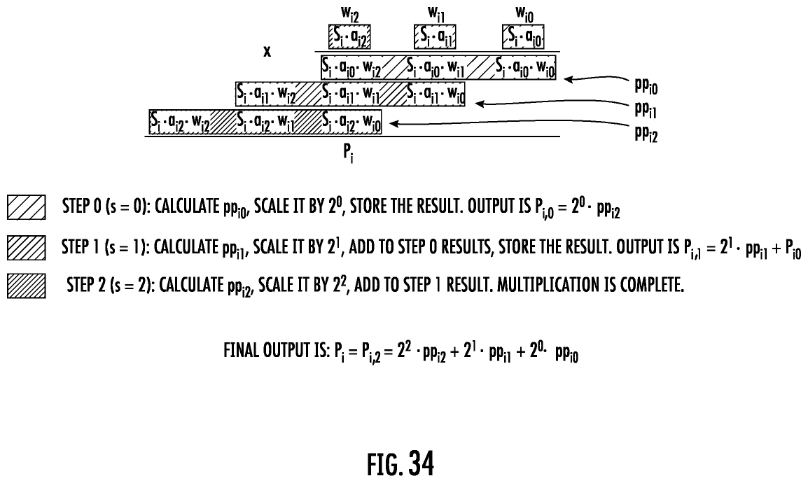

FIG. 33A illustrates an example of a MASAR array 150 implementing a serial arrangement for 4-bit signed integers, Nₚ=4-bit. This approach serializes the multiplication of the input activations with the weights. The multiplication may be performed in a sequence of operations, starting with the least significant activation bit, aᵢ₀ and ending with the (Nₚ−1)th bit.

FIG. 34 illustrates example operations performed for the 4-bit signed integer case using the MASAR array 150 of FIG. 33A. In these steps, partial products, ppᵢ₀ to ppᵢ₂ are computed. In step 0 (s=0) all terms in ppᵢ₀ (Sᵢ·aᵢ₀·wᵢ₂, Sᵢ·aᵢ₀·wᵢ₁, Sᵢ·aᵢ₀·wᵢ₀) are computed in parallel and then scaled by 2⁰. In step 1 (s=1) all terms in ppᵢ₁ are computed, scaled by 2¹ and added to the step 0 results. In step 2 (s=2) ppᵢ₂ is computed, scaled by 2² and added to the step 1's result. The output of step 2 is the final product, Pᵢ=Aᵢ·Wᵢ. While this example is shown in terms of signed integers, similar processing may be performed for two's complement values.

Referring back to FIG. 33A, FIG. 33A shows an implementation which performs the operations of FIG. 34 using simplified models of MASAR cells 104. Each cell has a SRAM 202 to store the weights as shown. In the 1^{st} column the sign bit of the multiplication is calculated using the most significant bits aᵢ₃ and wᵢ₃. In the remaining 3 columns the terms of the partial products are calculated in parallel and stored as charge on the columns. The inputs, aᵢₛ, and scale factor, 2^{s}, change for each step (s=0, 1, 2) of the multiplication. The charge on the columns representing the partial products is converted to digital prior to scaling. The previous steps output, Pᵢₛ₋₁, which has been stored in the register, is added to the current scaled output. The registers shown in FIG. 33A also store the current result of each step, P_{i,s}. At step=0, P_{i,s-1}=0. And P_{i,0}=2⁰·ppᵢ₀. At step=1, P_{i,s-1}=P_{i,0}. And P_{i,1}=2¹·ppᵢ₁+P_{i,0}. At step=2, P_{i,s-1}=P_{i,1}. And P_{i,2}=2²·ppᵢ₂+P_{i,1}=Pᵢ.

FIG. 33B shows a diagram of a serial MASAR product cell for Nₚ=4-bits with comparators 114 and digital logic 116. Note in this case only a 1-bit SAR ADC is required to convert each partial product. Also, only one row is required to compute the product, Pᵢ, while a parallel MASAR cell 104 requires Nₚ−1 rows. Generally, a serial product cell is ˜Nₚ times smaller than the parallel product cell and ˜Nₚ times slower perform one product or MAC.

The architecture shown in FIG. 33A implements only one serial 4-bit product. To implement multiple products in parallel one must add serial MASAR product cells to the columns (bit lines).

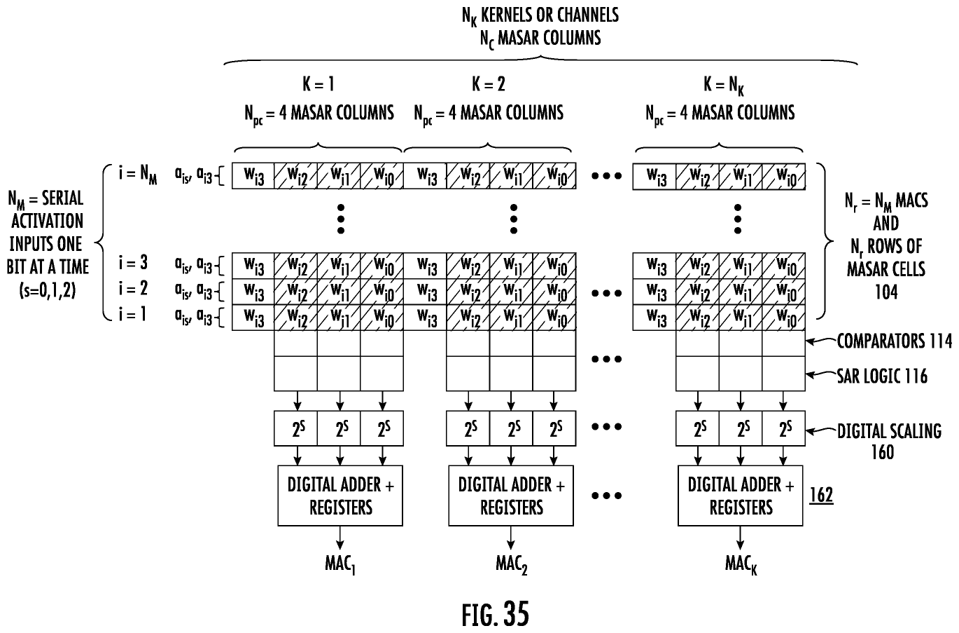

FIG. 35 illustrates an example serial 4-bit precision MASAR array 150 for computing a MAC with N_{M} products in K=N_{K} channels or kernels. As shown, there are i=1 to N_{M} rows in each channel. Each row can compute one product (in serial). Hence each channel can compute a N_{M} MACs with 4-bit precision, as provided in Eq. 22. As explained earlier, multiple channels/kernels can be placed in parallel to accommodate larger computations. This is also shown, where there are N_{K} channels. The activations may be broadcast along the rows of the channels. The weights may be stored in the SRAM 202 located in the MASAR cells 14. The sign bits may be calculated and routed along the row of each individual channel, similar to as shown in FIG. 33A.

It should also be noted that serial MASAR accelerators can be extended to higher or lower bit precision. For instance a Nₚ=16-bit precision accelerator that calculates N_{M} 16 bit MACs can be implemented with a 16 column by (N_{M}+1) row serial MASAR accelerator.

It should be noted that while many of the examples above are discussed in terms of signed integer values, the MASAR columns 102 and MASAR arrays 150 may also be used to perform two's-complement computations. Like unsigned numbers, N-bit two's complement numbers represent one of 2^{N} possible values, although with a different range. Thus, for two's complement computations, 2^{N} rows may be used for an N-bit output. However, for signed values, 2^{N+1} rows may be required for an N-bit output to account for the sign.

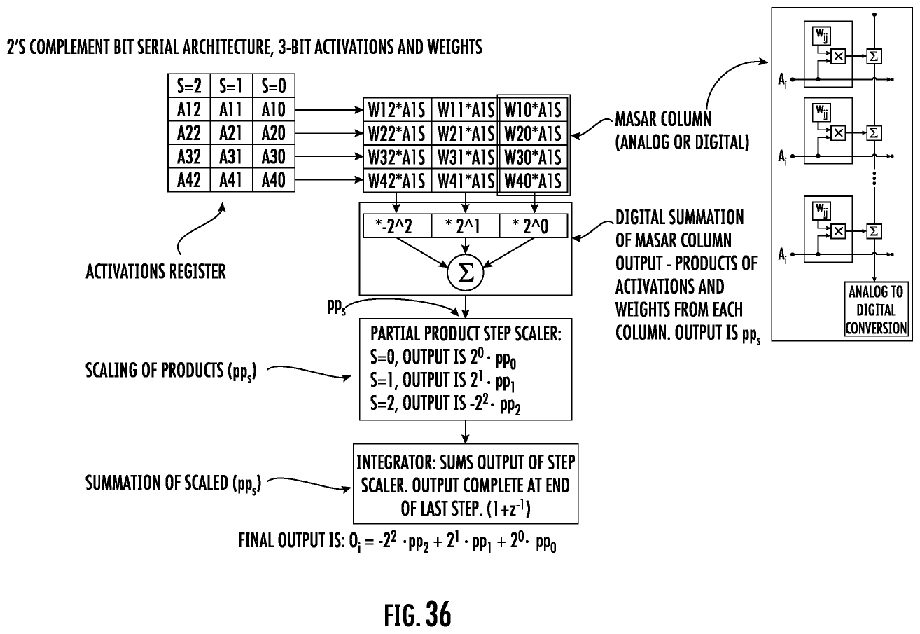

FIGS. 36-40 collectively illustrate an example of a serial 3-bit precision MASAR array 150 computation performed using two's complement. Similar to the signed examples discussed above, activations may be fed serially into the MASAR array 150. In FIG. 36, the input bits are fed from LSB to MSB, although other orderings are possible (FIG. 38-40). Partial products (PPs) are computed, similar to as shown in FIG. 34. An accumulator or integrator may add the scaled partial products to previous results until the final step of the computation is complete.

FIG. 36 illustrates an example two's complement bit serial architecture, using 3-bit activations and weights. As shown, the activations are fed into the MASAR column 102 bit by bit. Each activation is multiplied by a corresponding weight, where the weights may be stored close to the multipliers 204, e.g., in SRAMs 202. For each bit, a digital summation may be performed to produce a partial product for that bit position. These partial products are then scaled. For example, for a 3-bit two's complement number, the LSB bit is shifted by 2\hat{ }0, the next LSB is shifted by 2\hat{ }1, and the third bit is shifted by −2\hat{ }2. The sum of these three intermediate values is the final summation 162.

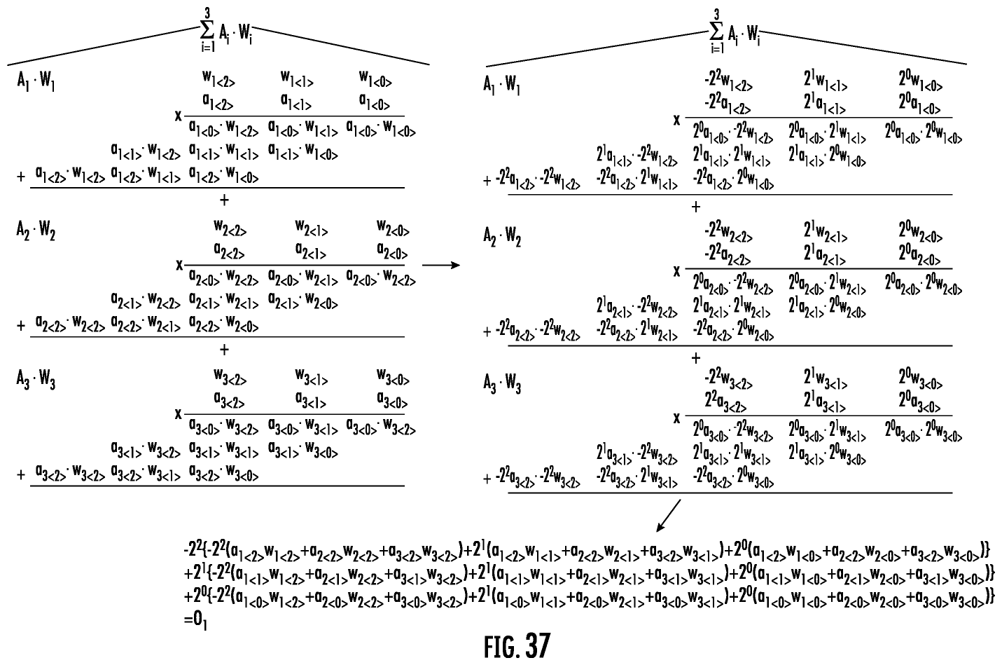

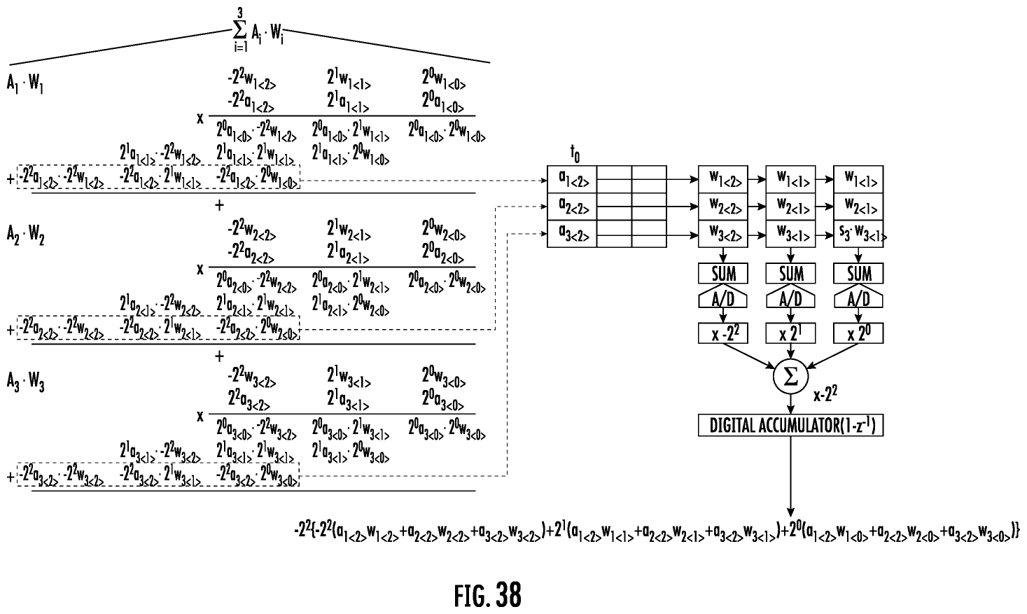

FIG. 37 illustrates an example of addition of the partial products of the serial computation performed by the architecture of FIG. 36. The left side shows the individual values that are summed to produce the partial products, while the right hand side additionally shows the shifts applied to each value of the partial products. The lower equations summarize these computations.

FIG. 38 illustrates an example of the first step of the computation of the partial products of FIG. 37. As shown, the MSB of the 3-bit computation is being performed using the MASAR column 102. This bit is shifted two positions to the left when added to the result, as well as reversed in sign.

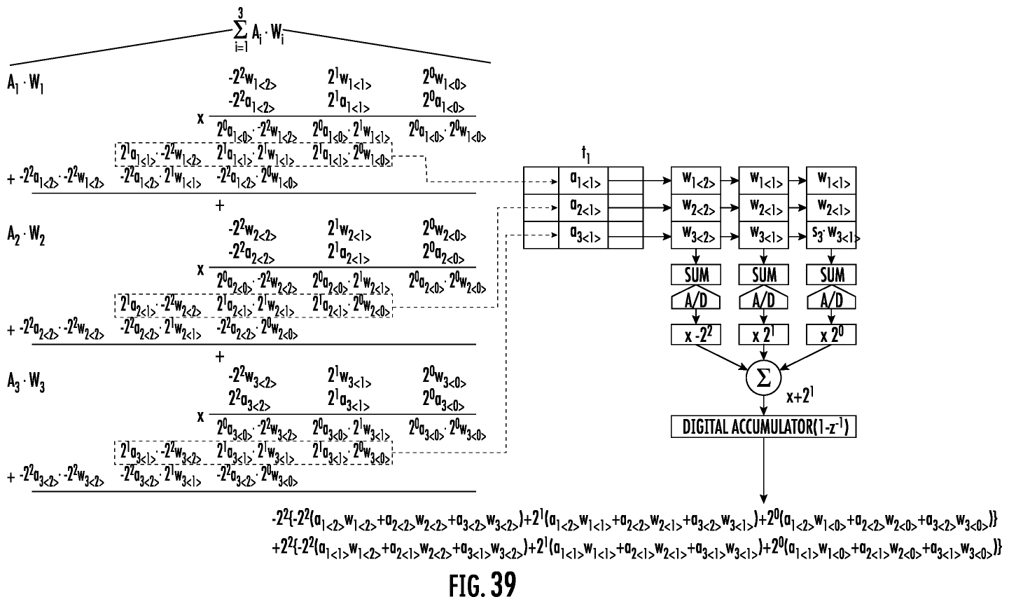

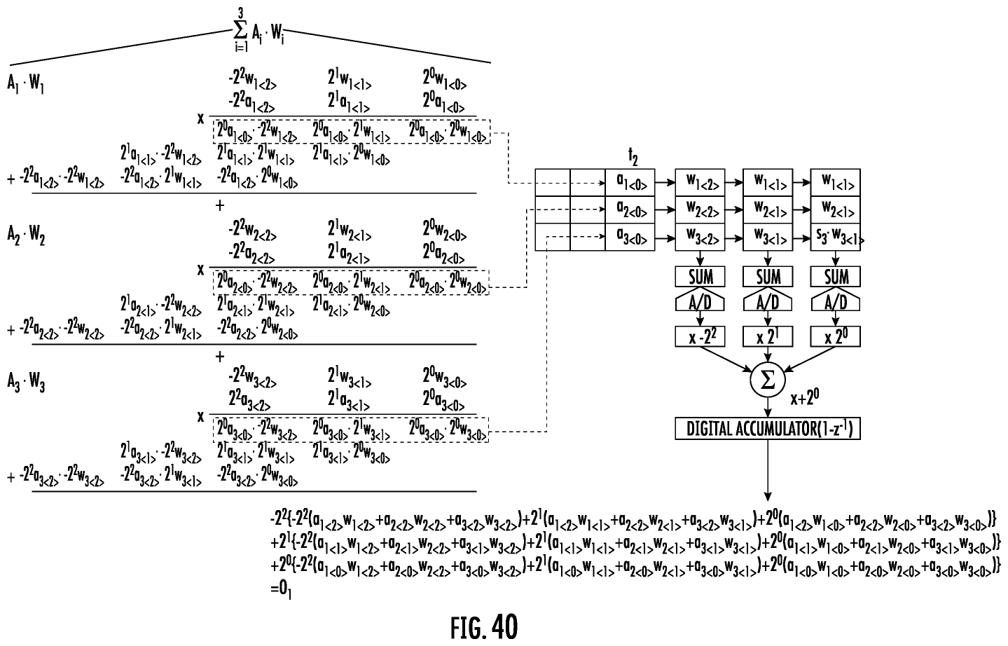

FIG. 39 illustrates an example of the second step of the computation of the partial products of FIG. 37. As shown, the middle bit of the 3-bit computation is being performed using the MASAR column 102. This bit is shifted one position to the left when added to the result.

FIG. 40 illustrates an example of the third step of the computation of the partial products of FIG. 37. As shown, the LSB of the 3-bit computation is being performed using the MASAR column 102. This bit does not require any shifting when added to the result.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the disclosure that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A multiply-accumulate successive approximation (MASAR) array for performing a plurality of parallel multiply-accumulate (MAC) calculations, comprising:
a plurality of MASAR columns, each MASAR column including a plurality of MASAR cells,
each of the MASAR cells including a multiplier configured to perform digital multiplication between an input activation received to an input and an operand to compute a result, and a unit capacitor configured to store the result as analog charge; and
global digital logic configured to control analog summation of the analog charge of the unit capacitors of the plurality of MASAR cells to determine a digital output of the multiplication by configuring the unit capacitors as a capacitive digital to analog converter (CDAC) in a successive approximation register (SAR) analog to digital converter (ADC).

2. The MASAR array of claim 1, further comprising:
a row driver configured to selectively connect a row driver input to a respective one of the inputs to the plurality of MASAR columns; and
global SAR digital logic, configured to utilize the row driver to iteratively connect to the input of each of the plurality of MASAR columns and to a respective comparator of the MASAR column to serially perform ADC conversion of the analog charge utilizing the global SAR digital logic for each of the plurality of MASAR columns.

3. The MASAR array of claim 2, wherein the global SAR digital logic is configured to apply ADC guess signals to the row driver input during SAR mode.

4. The MASAR array of claim 2, wherein each of the MASAR cells includes a memory, and the global SAR digital logic is configured to apply input activations to the row driver in a MAC mode, and to provide provides weight memory values for programming the operands to the memories in a weight programming mode.

5. The MASAR array of claim 1, wherein each of the plurality of MASAR columns includes local SAR digital logic, and the global digital logic is further configured to utilize the local SAR digital logic of each of the MASAR columns to perform parallel ADC conversion of the analog charge for each of the plurality of MASAR columns.

6. The MASAR array of claim 5, wherein the local SAR digital logic is configured to apply ADC guess signals through the respective MASAR column to each MASAR cell of the respective MASAR column.

7. The MASAR array of claim 5, wherein each of the MASAR cells includes a memory, and the global digital logic is configured to apply input activations to row drivers in a MAC mode, and to provide provides weight memory values for programming the operands to the memories in a weight programming mode.

8. The MASAR array of claim 1, wherein the digital output of each of the plurality of MASAR columns is an N bit value, and the plurality of MASAR cells of each MASAR column include at least 2^{N} cells.

9. A parallel multi-bit MASAR architecture for performing multi-bit multiplication, comprising:
a two-dimensional array of MASAR cells, configured to collectively multiply each digit of a multi-bit input activation by each digit of a multi-bit operand, the MASAR cells being arranged into MASAR columns by bit significance, such that summation is performed in analog via charge summation for each column to determine a single-bit digital output of the multiplication for each MASAR column;
a plurality of scalars, each configured to digitally scale the single-bit digital outputs of each MASAR column by the bit significance to produce scaled digital outputs; and
an adder configured to add the scaled digital outputs to produce a multi-bit digital result of the multiplication.

10. The parallel multi-bit MASAR architecture of claim 9, wherein each of the single-bit digital outputs of the multiplication for each MASAR column are computed in parallel.

11. The parallel multi-bit MASAR architecture of claim 9, wherein the multi-bit multiplication is a signed multiplication, and one of the MASAR cells of the array is a sign bit computed as the most significant bit of the multi-bit input activation times the most significant bit of the operand.

12. The parallel multi-bit MASAR architecture of claim 9, wherein one of the MASAR cells for each bit significance includes a memory configured to store a bit of the multi-bit operand corresponding to that respective bit significance, wherein the memory is shared to other bit significance positions of the two-dimensional array.

13. The parallel multi-bit MASAR architecture of claim 9, wherein each of the MASAR cells for each bit significance includes a memory configured to store a bit of the multi-bit operand corresponding to that respective bit significance.

14. The parallel multi-bit MASAR architecture of claim 9, wherein the two-dimensional array includes Nₚᵣ rows and N_{pc} columns of MASAR cells.

15. The parallel multi-bit MASAR architecture of claim 9, wherein the two-dimensional array includes a first subset of the columns for performing a first multiplication and a second subset of the columns for performing a second multiplication in parallel with the first multiplication.

16. The parallel multi-bit MASAR architecture of claim 9, wherein the two-dimensional array includes at least one zero input row are added to insure there are 2^{k} MASAR cells in each MASAR column, where k is a precision in bits of the multiplication.

17. The parallel multi-bit MASAR architecture of claim 9, wherein the two-dimensional array includes one or more zero input rows configured for input bias or calibration of the two-dimensional array.

18. A serial multi-bit MASAR architecture for performing multi-bit multiplication, comprising:
a single row of MASAR cells, configured to multiply a single bit of a multi-bit input activation by each digit of a multi-bit operand, the MASAR cells being arranged into MASAR columns by bit significance, such that summation is performed in analog via charge summation for each column to determine intermediate results of the multiplication for each single bit of the multi-bit input activation;
a plurality of scalars, each configured to digitally scale the intermediate results of each MASAR column by the bit significance to produce scaled digital outputs;
an adder configured to add the scaled digital outputs; and
control logic configured to iterate the single row of MASAR cells through each bit of the multi-bit input activation and to utilize the adder to sum a multi-bit digital result of the multiplication.

19. The serial multi-bit MASAR architecture of claim 18, further comprising registers, wherein the adder is configured to add the scaled digital outputs to the registers, and the control logic is configured to utilize the adder to sum the multi-bit digital result of the multiplication using the registers.

20. The serial multi-bit MASAR architecture of claim 18, wherein the control logic is configured to iterate through the bits of the multi-bit input activation from least significant bit to most significant bit.

21. The serial multi-bit MASAR architecture of claim 18, wherein the control logic is configured to iterate through the bits of the multi-bit input activation from most significant bit to least significant bit.

22. The serial multi-bit MASAR architecture of claim 18, wherein for signed integer values, the most significant bit of the multi-bit input activation is a sign bit.

23. The serial multi-bit MASAR architecture of claim 18, wherein the single row of MASAR cells includes a first subset of the columns for performing a first multiplication and a second subset of the columns for performing a second multiplication in parallel with the first multiplication.

24. The serial multi-bit MASAR architecture of claim 18, wherein each of the MASAR cells for each bit significance includes a memory configured to store a bit of the multi-bit operand corresponding to that respective bit significance.

25. The serial multi-bit MASAR architecture of claim 18, wherein the MASAR cells include Nₚᵣ rows and N_{pc} columns of MASAR cells.

26. The serial multi-bit MASAR architecture of claim 18, wherein the MASAR cells include at least one zero input row are added to insure there are 2^{k} MASAR cells in each MASAR column, where k is a precision in bits of the multiplication.

27. The serial multi-bit MASAR architecture of claim 18, wherein the MASAR cells include one or more zero input rows configured for input bias or calibration.
